(19) United States
(12) Patent Application Publication
(10) Pub. No.: US 2018/0040665 A1
(43) Pub. Date: Feb. 8, 2018

(54) DISPLAY APPARATUS AND ILLUMINATION APPARATUS, AND LIGHT EMITTING ELEMENT AND SEMICONDUCTOR DEVICE

(71) Applicant: Sony Semiconductor Solutions Corporation, Kanagawa (JP)

(72) Inventors: Akira Ohmae, Kanagawa (JP); Yusuke Kataoka, Kanagawa (JP); Tatsuo Ohashi, Kanagawa (JP); Ippei Nishinaka, Kanagawa (JP); Goshi Biwa, Kanagawa (JP)

(73) Assignee: Sony Semiconductor Solutions Corporation, Kanagawa (JP)

(21) Appl. No.: 15/554,914

(22) PCT Filed: Feb. 16, 2016
(86) PCT No.: PCT/JP2016/054408

§ 371 Date: Aug. 31, 2017

(30) Foreign Application Priority Data
Mar. 20, 2015 (JP) 2015-058649
Mar. 25, 2015 (JP) 2015-062394

(51) Int. Cl. H01L 27/15; H01L 33/36; F21V 19/00; H01L 33/46

(52) U.S. Cl. CPC H01L 27/156; H01L 33/46; H01L 33/36; F21V 19/0015; F21Y 2113/13

(57) ABSTRACT

A display apparatus according to one embodiment of the disclosure includes pixels in a plurality. The pixels are two-dimensionally disposed, and the pixels each include light emitting elements of at least a first primary color. The pixels each or pixel groups each include, as the light emitting elements of the first primary color, a first light emitting element and a second light emitting element that have peak wavelengths of light emission in different wavelength bands from each other. The pixel groups each include two or more adjacent ones of the pixels.

### TECHNICAL FIELD

The disclosure relates to a display apparatus and an illumination apparatus that utilize light emitting elements in primary colors, and a light emitting element that emits light in a stacking direction of semiconductors and a semiconductor device that includes the light emitting element.

### BACKGROUND ART

In recent years, there have been spreading illumination apparatuses and display apparatuses that are constituted by a group of a plurality of light emitting diodes (LEDs). Among them, LED displays are drawing attention as light-weighted and low-profile displays, with various improvements having been made in, for example, enhancement in light emission efficiency. The LED displays utilize the LEDs as display pixels.

For example, display apparatuses (LED displays) using three primary colors such as R (red), G (green), and B (blue) have high luminance and high color purity, and are in wide use as large-sized indoor or outdoor displays (For example, refer to PTL 1). In most of them, some independent modules are combined and arranged side by side (so-called tiling), allowing for achievement of large-sized displays without joints.

However, in light emitting elements such as the LEDs, in their manufacture processes, wavelengths deviate from design values wafer by wafer, or lot by lot. This easily causes variations between wafers or lots.

Moreover, in general, light emitting units utilized in displays include the light emitting elements (e.g., the LEDs) of a plurality of colors. The light emitting elements are arranged in a casing including, for example, a resin or glass. Alternatively, the light emitting units utilized in the displays are constituted by systems such as liquid crystal. Light generated in the LEDs in the light emitting units is not only emitted to outside through upper surfaces of the light emitting units, but also is propagated through an inside of the casing. If the light propagated in the inside of the casing enters the LEDs of different colors, there is caused degradation of the elements or light emission of the elements. This results in crosstalk in a displayed picture, a change in chromaticity, or a decreased range of color reproduction.

In regards to this, for example, PTL 1 as mentioned above discloses a light emitting element (an LED) whose side surfaces and bottom surface are covered with a stacked body including an insulating layer and a metal layer. This leads to reduction in undesirable influences by the light propagated in the light emitting units.

### CITATION LIST

### Patent Literature

PTL 1: Japanese Unexamined Patent Application Publication No. 2012-182276

### SUMMARY OF THE INVENTION

However, the light emitting element described in PTL 1 has deviation of viewing angle characteristics, in particular, a far field pattern (FFP), because of its structure. The deviation differs according to colors of light emitted. Accordingly, the display apparatus utilizing the LEDs as the light emitting elements has a disadvantage of non-uniformity of displayed pictures. That is, the displayed pictures are of different RGB ratios between a case where the display is viewed from front and a case where the display is viewed obliquely.

Furthermore, with such light emitting elements disposed in each pixel, desired hues and brightness are not represented, causing degradation in quality. In the display apparatus or the illumination apparatus utilizing the light emitting elements, there has been desire for achievement of a technique that makes it possible to attain enhancement in quality.

It is therefore desirable to provide a display apparatus and an illumination apparatus that make it possible to achieve enhancement in quality. Moreover, it is desirable to provide a light emitting element and a semiconductor device that make it possible to reduce deviation of viewing angle characteristics.

A display apparatus according to an embodiment of the disclosure includes pixels in a plurality. The pixels are two-dimensionally disposed, and the pixels each include light emitting elements of at least a first primary color. The pixels each or pixel groups each include, as the light emitting elements of the first primary color, a first light emitting element and a second light emitting element that have peak wavelengths of light emission in different wavelength bands from each other. The pixel groups each include two or more adjacent ones of the pixels.

In the display apparatus according to the embodiment of the disclosure, the pixels each or the pixel groups each include, as the light emitting elements of the first primary color, the first light emitting element and the second light emitting element that have the peak wavelengths of the light emission in the different wavelength bands from each other. The pixel groups each include the two or more adjacent ones of the pixels. Accordingly, it is possible to provide picture display utilizing a composite wavelength of the wavelengths of the first light emitting element and the second light emitting element, as a wavelength of the first primary color in the pixel or in the pixel group.

An illumination apparatus according to an embodiment of the disclosure includes units in a plurality. The units are two-dimensionally disposed, and the units each include light emitting elements of at least a first primary color. The units each or unit groups each include, as the light emitting elements of the first primary color, a first light emitting element and a second light emitting element that have peak wavelengths of light emission in different wavelength bands from each other. The unit groups each include two or more adjacent ones of the pixels.

In the illumination apparatus according to the embodiment of the disclosure, the units each or the unit groups each include, as the light emitting elements of the first primary color, the first light emitting element and the second light emitting element that have the peak wavelengths of the light emission in the different wavelength bands from each other. The unit groups each include the two or more adjacent ones of the units. Accordingly, it is possible to provide light emission utilizing the composite wavelength of the wavelengths of the first light emitting element and the second light emitting element, as the wavelength of the first primary color in the unit or in the unit group.

A first light emitting element according to an embodiment of the disclosure includes a semiconductor layer, a first electrode, and a second electrode. The semiconductor layer has a first surface and a second surface, and includes a stack of a first conductive type layer, an active layer, and a second conductive type layer in order from side on which the first surface is disposed. The first electrode is electrically coupled to the first conductive type layer and is provided on the first surface. The second electrode is electrically coupled to the second conductive type layer and is provided on the first surface. The second electrode is thicker than the first electrode.

A second light emitting element according to an embodiment of the disclosure includes a semiconductor layer, a first electrode, and a second electrode. The semiconductor layer has a first surface and a second surface, and includes a stack of a first conductive type layer, an active layer, and a second conductive type layer in order from side on which the first surface is disposed. The first electrode is electrically coupled to the first conductive type layer and is provided on the first surface. The first electrode has a thickness varied in an in-plane direction. The second electrode is electrically coupled to the second conductive type layer and is provided in in-plane asymmetry in the second surface.

A first semiconductor device according to an embodiment of the disclosure includes a plurality of the first light emitting elements according to the embodiment as mentioned above.

A second semiconductor device according to an embodiment of the disclosure includes a plurality of the second light emitting elements according to the embodiment as mentioned above.

In the first light emitting element according to the embodiment of the disclosure and the semiconductor device according to the embodiment, the semiconductor layer has the first surface and the second surface, and includes the stack of the first conductive type layer, the active layer, and the second conductive type layer in the order from the side on which the first surface is disposed. The first electrode and the second electrode are provided on the first surface. The first electrode is electrically coupled to the first conductive type layer. The second electrode is electrically coupled to the second conductive type layer. The second electrode is larger in thickness than the first electrode. Accordingly, deviation of light emitted from the active layer is corrected.

In the second light emitting element according to the embodiment of the disclosure and the semiconductor device according to the embodiment, the semiconductor layer has the first surface and the second surface, and includes the stack of the first conductive type layer, the active layer, and the second conductive type layer in the order from the side on which the first surface is disposed. The first electrode is provided on the first surface, on opposite side to the second electrode, with the semiconductor layer in between. The second electrode is electrically coupled to the second conductive type layer and is provided in the in-plane asymmetry in the second surface. The first electrode has the thickness varied in the in-plane direction. Accordingly, the deviation of the light emitted from the active layer is corrected.

According to the display apparatus of the embodiment of the disclosure, the pixels each or the pixel groups each include, as the light emitting elements of the first primary color, the first light emitting element and the second light emitting element that have the peak wavelengths of the light emission in the different wavelength bands from each other. The pixel groups each include the two or more adjacent ones of the pixels. Accordingly, even in a case where the wavelengths of the light emitting elements of the first primary color vary in an image surface because of, for example, manufacture processes, it is possible to reduce influences on display by the variations in the wavelengths. This makes it possible to represent desired hues and brightness. Hence, it is possible to achieve enhancement in quality (image quality).

According to the illumination apparatus of the embodiment of the disclosure, the units each or the unit groups each include, as the light emitting elements of the first primary color, the first light emitting element and the second light emitting element that have the peak wavelengths of the light emission in the different wavelength bands from each other. The unit groups each include the two or more adjacent ones of the pixels. Accordingly, even in a case where the wavelengths of the light emitting elements of the first primary color vary in a light emission surface because of, for example, the manufacture processes, it is possible to reduce influences on illumination light by the variations in the wavelengths. This makes it possible to represent the desired hues and brightness. Hence, it is possible to achieve enhancement in quality (illumination quality).

According to the first and the second light emitting elements of the embodiments of the disclosure and the semiconductor devices of the embodiments, in the first light emitting element, the second electrode is larger in thickness than the first electrode. In the second light emitting element, the first electrode has the thickness varied in the in-plane direction. Accordingly, the deviation of the light emitted from the active layer is corrected. Hence, it is possible to reduce deviation of the viewing angle characteristics.

It is to be noted that the forgoing contents are one example of the disclosure. Effects of the disclosure are not necessarily limited to the effects described above, and may be other different effects or may further include other effects.

### BRIEF DESCRIPTION OF DRAWING

FIG. 1 is a block diagram that illustrates an overall configuration of a display apparatus according to a first embodiment of the disclosure.

FIG. 2 is a schematic plan view of a configuration example of a pixel illustrated in FIG. 1.

FIG. 3 is a characteristic diagram provided for description of a distance between blue light emitting elements illustrated in FIG. 2.

FIG. 4 is a characteristic diagram provided for the description of the distance between the blue light emitting elements illustrated in FIG. 2.

FIG. 5 is a characteristic diagram that illustrates relation between an inch size and a pixel pitch.

FIG. 6 is a characteristic diagram that illustrates relation of a recommended viewing distance, the pixel pitch, and the inch size.

FIG. 7 is a schematic diagram provided for description of wavelength variations of pixels according to a comparative example.

FIG. 8 is a characteristic diagram that illustrates chromaticity of each of R, G, and B of the pixels according to the comparative example.

FIG. 9 is a schematic diagram provided for description of wavelength variations of the pixels as illustrated in FIG. 2.

FIG. 10A is a characteristic diagram that illustrates one example of two wavelengths of a blue color in a first pixel illustrated in FIG. 9, and a composite wavelength of these two wavelengths.

FIG. 10B is a characteristic diagram that illustrates one example of the two wavelengths of the blue color in a second pixel illustrated in FIG. 9, and the composite wavelength of these two wavelengths.

FIG. 10C is a characteristic diagram that illustrates one example of the two wavelengths of the blue color in a third pixel illustrated in FIG. 9, and the composite wavelength of these two wavelengths.

FIG. 11 is a characteristic diagram that illustrates chromaticity of each of R, G, and B of the pixels illustrated in FIG. 9.

FIG. 12 is a perspective view of a configuration of a display unit according to an application example.

FIG. 13 is a perspective view of a configuration of a tiling device according to the application example.

FIG. 14A is a schematic plan view of a configuration example of a pixel according to a modification example 1-1.

FIG. 14B is a schematic plan view of a configuration example of a pixel according to a modification example 1-2.

FIG. 15A is a schematic plan view of a configuration example of a pixel according to a modification example 2-1.

FIG. 15B is a schematic plan view of a configuration example of a pixel according to a modification example 2-2.

FIG. 15C is a schematic plan view of a configuration example of a pixel according to a modification example 2-3.

FIG. 16A is a schematic plan view of a configuration example of a pixel according to a modification example 3-1.

FIG. 16B is a schematic plan view of a configuration example of a pixel according to a modification example 3-2.

FIG. 16C is a schematic plan view of a configuration example of a pixel according to a modification example 3-3.

FIG. 17A is a schematic plan view of a configuration example of a pixel according to a modification example 4-1.

FIG. 17B is a schematic plan view of a configuration example of a pixel according to a modification example 4-2.

FIG. 18A is a schematic plan view of a configuration example of pixels according to a modification example 5-1.

FIG. 18B is a schematic plan view of a configuration example of pixels according to a modification example 5-2.

FIG. 19A is a schematic plan view of a configuration example of pixels according to a modification example 6-1.

FIG. 19B is a schematic plan view of a configuration example of pixels according to a modification example 6-2.

FIG. 20A is a schematic plan view of a configuration example of pixels according to a modification example 7-1.

FIG. 20B is a schematic plan view of a configuration example of pixels according to a modification example 7-2.

FIG. 20C is a schematic plan view of a configuration example of pixels according to a modification example 7-3.

FIG. 21 is a characteristic diagram provided for description of correction of a G wavelength according to a modification example 8.

FIG. 22 is a characteristic diagram provided for description of correction of an R wavelength according to a modification example 8.

FIG. 23 is a characteristic diagram that illustrates one example of an absorption spectrum of a QD (quantum dot) filter according to a modification example 9.

FIG. 24 is a characteristic diagram that illustrates one example of a light emission spectrum of the QD filter illustrated in FIG. 23.

FIG. 25 is a characteristic diagram provided for description of a function of wavelength conversion of the QD filter according to the modification example 9.

FIG. 26 is a schematic diagram that illustrates a configuration of a main part of an illumination apparatus according to a second embodiment of the disclosure.

FIG. 27 is a schematic plan view of a configuration example of a unit illustrated in FIG. 26.

FIG. 28A is a cross-sectional view of one example of a configuration of a light emitting element according to a third embodiment of the disclosure.

FIG. 28B is a plan view of the configuration of the light emitting element illustrated in FIG. 28A.

FIG. 29A is a perspective view of one example of a configuration of a light emitting unit including a plurality of the light emitting elements illustrated in FIG. 28A.

FIG. 29B is a cross-sectional view of one example of the configuration of the light emitting unit illustrated in FIG. 29A.

FIG. 30 is polar coordinates that illustrate deviation of light emission of a light emitting element as a comparative example.

FIG. 31 is orthogonal coordinates that illustrate the deviation of the light emission of the light emitting element as the comparative example.

FIG. 32A is a plan view of a configuration of the light emitting element as the comparative example.

FIG. 32B is a cross-sectional view along a line II-II of the light emitting element illustrated in FIG. 32A.

FIG. 32C is a cross-sectional view along a line III-III of the light emitting element illustrated in FIG. 32A.

FIG. 33 is a schematic cross-sectional view of inclination of light in a case where the light emitting element illustrated in FIGS. 32A to 32C is mounted on a substrate.

FIG. 34 is orthogonal coordinates of the light emitting element illustrated in FIG. 28A.

FIG. 35 is a viewing angle characteristic diagram of panels including the light emitting elements illustrated in FIGS. 28A and 32A.

FIG. 36 is a cross-sectional view of another example of the configuration of the light emitting element according to the third embodiment of the disclosure.

FIG. 37 is a cross-sectional view of another example of the configuration of the light emitting element according to the third embodiment of the disclosure.

FIG. 38A is a cross-sectional view of one example of a configuration of a light emitting element according to a fourth embodiment of the disclosure.

FIG. 38B is a plan view of one example of the configuration of the light emitting element illustrated in FIG. 38A.

FIG. 39A is a perspective view of one example of a configuration of a light emitting unit including a plurality of the light emitting elements illustrated in FIGS. 38A and 38B.

FIG. 39B is a cross-sectional view of one example of the configuration of the light emitting unit illustrated in FIG. 39A.

FIG. 40 is a schematic cross-sectional view of inclination of light in a case where light emitting element as a comparative example is mounted on a substrate.

FIG. 41 is a diagram that illustrates a light distribution characteristic with respect to a central position of the light emitting element illustrated in FIG. 40.

FIG. 42 is a diagram that illustrates a light distribution characteristic with respect to a central position of the light emitting element illustrated in FIGS. 38A and 38B.

FIG. 43 is a cross-sectional view of another example of the configuration of the light emitting element according to the fourth embodiment of the disclosure.

FIG. 44 is a plan view of another example of the configuration of the light emitting element illustrated in FIGS. 38A and 38B.

FIG. 45 is a plan view of another example of the configuration of the light emitting element illustrated in FIGS. 38A and 38B.

FIG. 46 is a perspective view of one example of a configuration of a display unit as an application example.

FIG. 47 is a schematic diagram that illustrates one example of layout of the display unit illustrated in FIG. 46.

FIG. 48A is a plan view of one example of an illumination apparatus as an application example.

FIG. 48B is a perspective view of the illumination apparatus illustrated in FIG. 48A.

FIG. 49A is a plan view of another example of the illumination apparatus as the application example.

FIG. 49B is a perspective view of the illumination apparatus illustrated in FIG. 49A.

FIG. 50A is a plan view of another example of the illumination apparatus as the application example.

FIG. 50B is a perspective view of the illumination apparatus illustrated in FIG. 50A.

### MODES FOR CARRYING OUT THE INVENTION

In the following, some embodiments of the disclosure are described in detail with reference to the drawings. It is to be noted that description is made in the following order.

1. First Embodiment (an example of a display apparatus that performs display with the utilization of two kinds of blue light emitting elements disposed in a pixel)
1-1. Configuration
1-2. Workings and Effects
   2. Modification Examples 1-4 (examples of variations in which the two kinds of the blue light emitting elements are disposed in the pixel)
   3. Modification Examples 5-7 (examples of cases where the two kinds of the blue light emitting elements are disposed in a pixel group)
   4. Modification Example 8 (an example of a case where two kinds of green light emitting elements and two kinds of red light emitting elements are disposed as well)
   5. Modification Example 9 (an example of a case with the utilization of a QD filter)
   6. Second Embodiment (an example of an illumination apparatus that performs light emission with the utilization of two kinds of blue light emitting elements disposed in a unit)
   7. Third Embodiment (an example of a light emitting element including electrodes on a lower surface of a semiconductor layer)
7-1. Configuration of Light Emitting Element
7-2. Configuration of Light Emitting Unit
7-3. Workings and Effects
   8. Fourth Embodiment (an example of a light emitting element including electrodes on an upper surface and a lower surface of a semiconductor layer)
8-1. Configuration of Light Emitting Element
8-2. Configuration of Light Emitting Unit
8-3. Workings and Effects

### 9. Application Example

### First Embodiment

### 1-1. Configuration

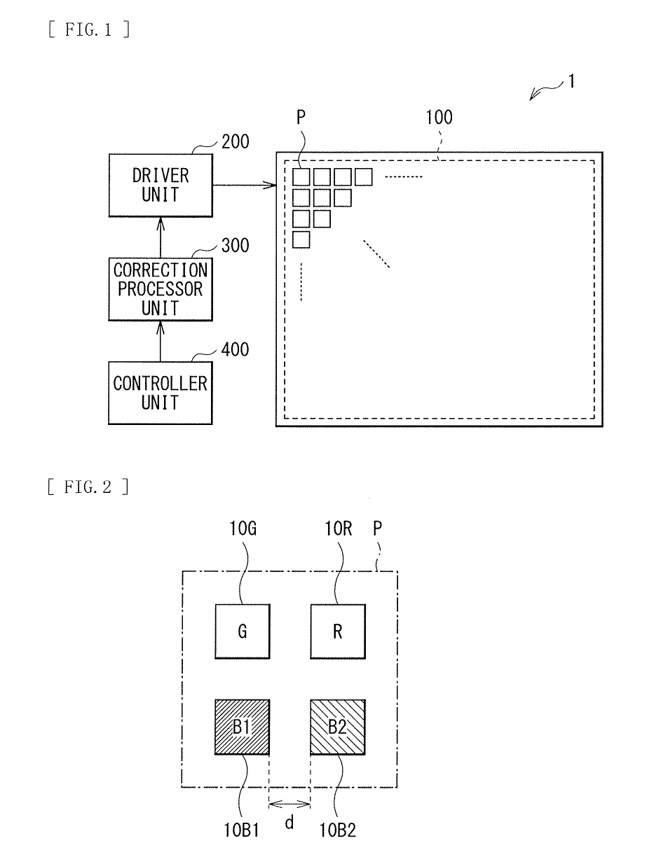

FIG. 1 illustrates an overall configuration of a display apparatus (a display apparatus 1) according to a first embodiment of the disclosure. The display apparatus 1 includes, for example, a pixel array unit 100, a driver unit 200, a correction processor unit 300, and a controller unit 400. The pixel array unit 100 is so constituted as to include, for example, a plurality of pixels P.

The pixel array unit 100 includes, for example, the plurality of the pixels P that are two-dimensionally disposed. In the single pixel P, disposed are light emitting elements that emit light of two or more primary colors (here, three primary colors of R, G, and B). Examples of the light emitting elements include light emitting diodes (LEDs) that emit color light in red (R), green (G), and blue (B). A red LED (a red light emitting element) is made of, for example, AlGaInP-based materials. A green LED (a green light emitting element) and a blue LED (a blue light emitting element) are made of, for example, AlGaInN-based materials. In the pixel array unit 100, each of the pixels P is pulse driven on the basis of a picture signal inputted from outside. Thus, luminance of each LED is adjusted, and a picture is displayed.

The driver unit 200 performs a display drive of each of the pixels P of the pixel array unit 100, and is so constituted as to include, for example, a constant current driver. The driver unit 200 is configured to drive each of the pixels P by, for example, pulse width modulation (PWM), with the utilization of a drive signal after correction. The drive signal after the correction is supplied from the correction processor unit 300.

The correction processor unit 300 is a signal processor unit that makes the correction of the drive signal of the light emitting elements disposed in the pixel P, on the basis of, for example, a correction coefficient held in advance (data regarding a composite ratio (an output ratio) of two kinds of wavelengths described later). The correction coefficient is set for each of the pixels P, and stored in an undepicted data memory.

The controller unit 400 is so constituted as to include, for example, a micro-processing unit (MPU). The controller unit 400 controls the correction processor unit 300 and the driver unit 200.

### [Detailed Configuration of Pixel P]

FIG. 2 illustrates a configuration example of the pixel P. As described above, in the pixel array unit 100, in the single pixel P, disposed are the light emitting elements of the three primary colors of R, G, and B. In this embodiment, as the light emitting elements of a blue color (a first primary color) out of the three primary colors of R, G, and B, included are two kinds of the light emitting elements (blue light emitting elements 10B1 and 10B2). In this example, the light emitting elements (a green light emitting element 10G and a red light emitting element 10R) of the other primary colors (a green color and a red color) than the blue color are each disposed in a singularity. Moreover, in the pixel P, the red light emitting element 10R, the green light emitting element 10G, and the blue light emitting elements 10B1 and 10B2 are disposed in two rows and two columns as a whole (to form a 2×2 arrangement). The blue light emitting elements 10B1 and 10B2 are disposed side by side along a row direction (a left-right direction in the figure). The blue light emitting elements 10B1 and 10B2 serve as specific examples of a “first light emitting element” and a “second light emitting element” in the disclosure.

The red light emitting element 10R is a light emitting element that emits red color light of a wavelength of, for example, 625 nm to 740 nm both inclusive. The red light emitting element 10R is constituted by, for example, the red LED as mentioned above, and has a peak wavelength of light emission (a wavelength at which intensity of the light emission becomes a maximum value) in a wavelength band used in the red LED. The green light emitting element 10G is a light emitting element that emits green color light of a wavelength of, for example, 500 nm to 565 nm both inclusive. The green light emitting element 10G is constituted by, for example, the green LED as mentioned above, and has the peak wavelength of the light emission in a wavelength band used in the green LED.

Each of the blue light emitting elements 10B1 and 10B2 is a light emitting element that emits blue color light of a wavelength of, for example, 450 nm to 485 nm both inclusive. The blue light emitting elements 10B are constituted by, for example, the blue LEDs as mentioned above, and have the peak wavelengths of the light emission in wavelength bands used in the blue LEDs. In this embodiment, the blue light emitting elements 10B1 and 10B2 have the peak wavelengths of the light emission in different wavelength bands from each other. For example, the blue light emitting element 10B1 has the peak wavelength of the light emission in a partial wavelength band Wb1 in the above-mentioned wavelength range (the wavelength of 450 nm to 485 nm both inclusive) of the blue color. The blue light emitting element 10B2 has the peak wavelength of the light emission in a wavelength band Wb2 that is different from the wavelength band Wb1, in the wavelength range of the blue color as mentioned above. However, the wavelength band Wb1 and the wavelength band Wb2 may overlap with each other. It is to be noted that in this specification, the terms the “wavelength” and a “design wavelength” in the light emitting element mean a wavelength at which the intensity of the light emission peaks (the peak wavelength of the light emission).

The wavelength band Wb1 is a wavelength range including the design wavelength of the blue light emitting element 10B1, and includes, for example, the design wavelength of the blue light emitting element 10B1 and wavelengths in a range of manufacture errors (e.g., about −5 nm to +5 nm both inclusive) with respect to the design wavelength. The wavelength band Wb2 is a wavelength range including the design wavelength of the blue light emitting element 10B2, and includes, for example, the design wavelength of the blue light emitting element 10B2 and the wavelengths in the range of the manufacture errors (e.g., about −5 nm to +5 nm both inclusive) with respect to the design wavelength.

A difference between the design wavelengths of the blue light emitting elements 10B1 and 10B2 may be set at about 10 nm in consideration of, for example, the manufacture errors (e.g., about −5 nm to +5 nm both inclusive). Moreover, with the difference between the design wavelengths of the blue light emitting elements 10B1 and 10B2 being too large, a peak in a composite wavelength separates itself (into two peaks). Accordingly, it is desirable that the difference be set as a wavelength difference small enough to restrain the separation of the peak. The difference between the wavelengths of the respective blue light emitting elements 10B1 and 10B2 disposed in the pixel P is, for example, 5 nm to 30 nm both inclusive, although the difference varies for each of the pixels P.

The wavelengths of the respective blue light emitting elements 10B1 and 10B2 as mentioned above are dealt with as the composite wavelength for each of the pixels P. The composite ratio (the output ratio) of the wavelengths of the respective blue light emitting elements 10B1 and 10B2 are set in advance for each of the pixels P, and stored in the correction processor unit 300 as the correction coefficient. For example, in the manufacture processes, the wavelengths of the respective blue light emitting elements 10B1 and 10B2 are measured for each of the pixels P. The appropriate composite ratio (the output ratio) is set for each of the pixels P, to allow the composite wavelength of the two wavelengths thus measured to be substantially constant over the whole image surface. The data regarding the output ratio of the blue light emitting elements 10B1 and 10B2 is stored in the correction processor unit 300 as the correction coefficient.

It is desirable that the blue light emitting elements 10B1 and 10B2 be close to each other, to allow a distance d from the blue light emitting element 10B1 to the blue light emitting element 10B2 to be equal to or smaller than a predetermined distance. Thus, the wavelengths of the respective blue light emitting elements 10B1 and 10B2 are combined (into the composite wavelength) to spuriously represent the blue color of the single pixel P. It is desirable that the distance d be set at magnitude that is substantially undistinguishable for a human eye (so as to be equal to or smaller than a resolution distance for the eye, in which the resolution distance varies with a viewing distance). This makes it possible to allow a border between the blue light emitting elements 10B1 and 10B2 to become less visible, and to provide more natural display.

It is to be noted that specific configurations of the blue light emitting elements 10B1 and 10B2, the green light emitting element 10G, and the red light emitting element 10R are described later.

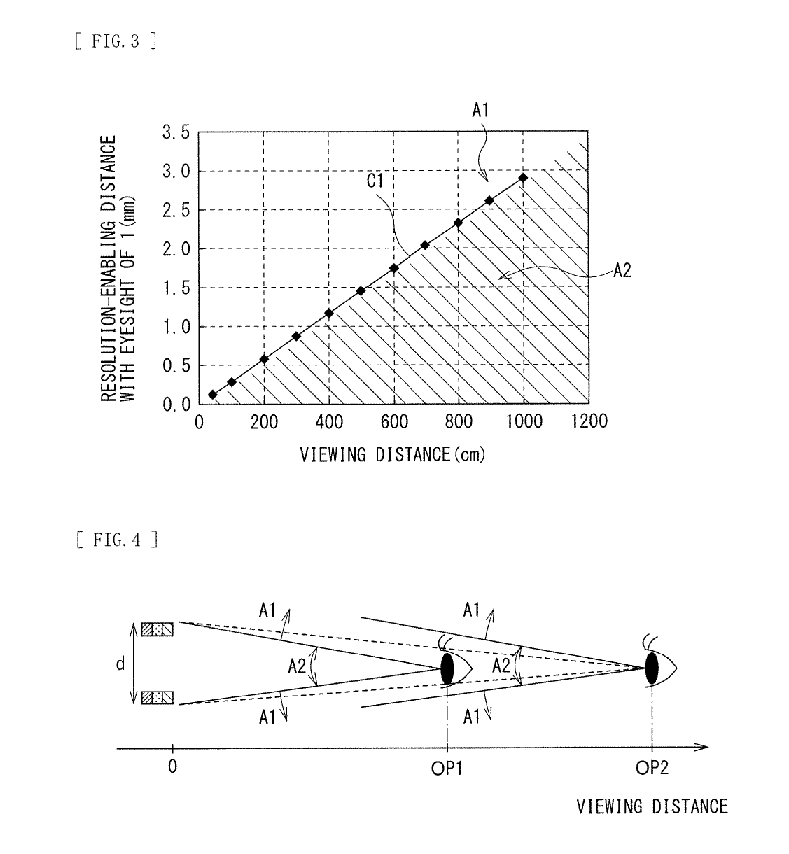

Here, FIGS. 3 and 4 illustrate relation between the viewing distance (a distance from a viewing object to the eye) and the resolution-enabling distance for the human eye. It is to be noted that FIG. 3 illustrates characteristics with eyesight of 1. As illustrated, there is limitation on a distance that is distinguishable for the human eye. As the viewing distance becomes larger, the resolution-enabling distance also becomes larger. For example, as illustrated in FIG. 4, a resolution-enabling range A1 and a resolution-unable range A2 at a position of a viewing distance OP1 are different from the resolution-enabling range A1 and the resolution-unable range A2 at a position of a viewing distance OP2 (>OP1). Moreover, in FIG. 3, a range of or above the resolution-enabling distance with respect to the viewing distance (a range on upper side of a resolution line c1) serves as the resolution-enabling range A1. A range of or below the resolution-enabling distance (a range on lower side of the resolution line c1: a hatched part) serves as the resolution-unable range A2 that is undistinguishable for the human eye.

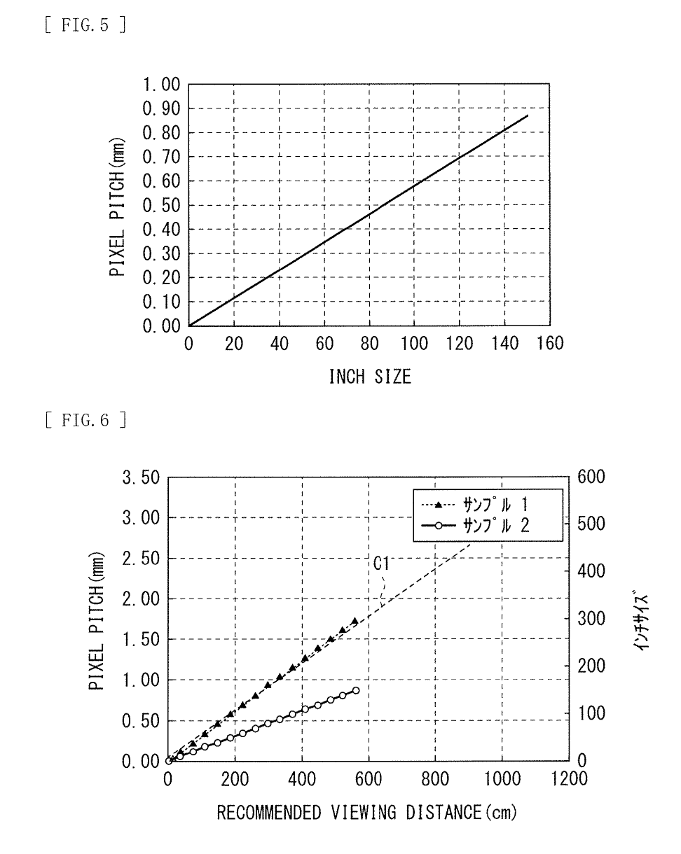

Meanwhile, as illustrated in FIG. 5, a pixel pitch (a pixel width) is set at a value that accords with a screen size (an inch size) of the pixel array unit 100. Moreover, in a field of displays, optimal viewing distances (recommended viewing distances) are specified in accordance with the inch sizes.

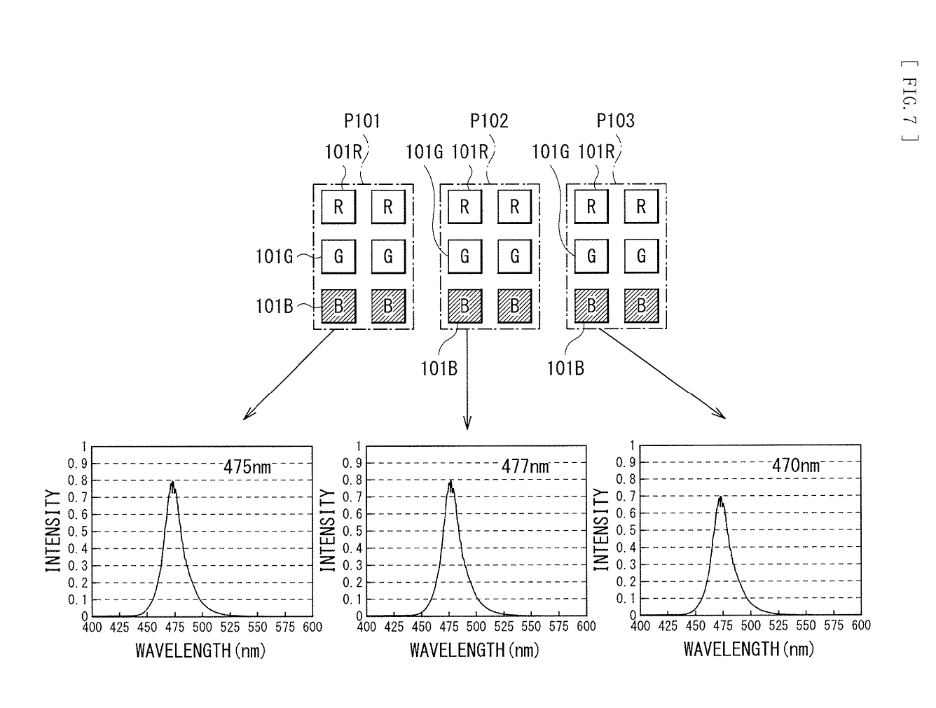

FIG. 6 illustrates relation between the pixel pitch and the inch size, and the recommended viewing distance. As one example, illustrated are the recommended viewing distances of a display (a sample 1) of resolution of an order of about 2000×1000 pixels and of a display (a sample 2) of resolution of an order of about 4000×2000 pixels. At the recommended viewing distance of the sample 2, the pixel pitch becomes equal to or smaller than the resolution distance. Accordingly, the border between the blue light emitting elements 10B1 and 10B2 becomes less visible, making it possible to achieve the more natural display. Meanwhile, at the recommended viewing distance of the sample 1, although the pixel pitch is slightly larger than the resolution distance, the pixel pitch is regarded as being at the substantially same level, and there is no substantial decrease in visibility. As described, adopting the pixel P according to this embodiment in a display of existing resolution makes it possible to obtain effects of the composite wavelength (apparent uniformization of wavelengths) as described later.

### 1-2. Workings and Effects

In the display apparatus 1 of this embodiment, the driver unit 200 supplies a drive current (outputs the drive signal) to each pixel of the pixel array unit 100, on the basis of the picture signal inputted from the outside. In each of the pixels P, each of the LEDs of the three primary colors of R, G, and B (the red light emitting element 10R, the green light emitting element 10G, and the blue light emitting elements 10B1 and 10B2) emits light at predetermined luminance, on the basis of the drive current supplied. A picture is displayed on the pixel array unit 100 by additive color mixture of the three primary colors in each of the pixels P.

However, the display apparatus 1 utilizing the LEDs as described above is likely to have variations in the wavelengths of the light emission of the light emitting elements, because of, for example, the manufacture processes. The variations in the wavelengths become a hindrance to representation of desired hues and brightness in the picture displayed, causing degradation in image quality.

FIG. 7 illustrates one example of a configuration of pixels according to a comparative example of this embodiment, and wavelengths of the blue color in each pixel. As illustrated, in a case where red light emitting elements 101R, green light emitting elements 101G, and blue light emitting elements 101B are disposed in, for example, each of adjacent pixels P101, P102, and P103, wavelengths of the light emitting elements are deviated pixel by pixel from a design value, causing variations between the pixels P101, P102, and P103. Specifically, a wavelength of the blue light emitting elements 101B of the pixel P101 is 475 nm. A wavelength of the blue light emitting elements 101B of the pixel P102 is 477 nm. A wavelength of the blue light emitting elements 101B of the pixel P103 is 470 nm.

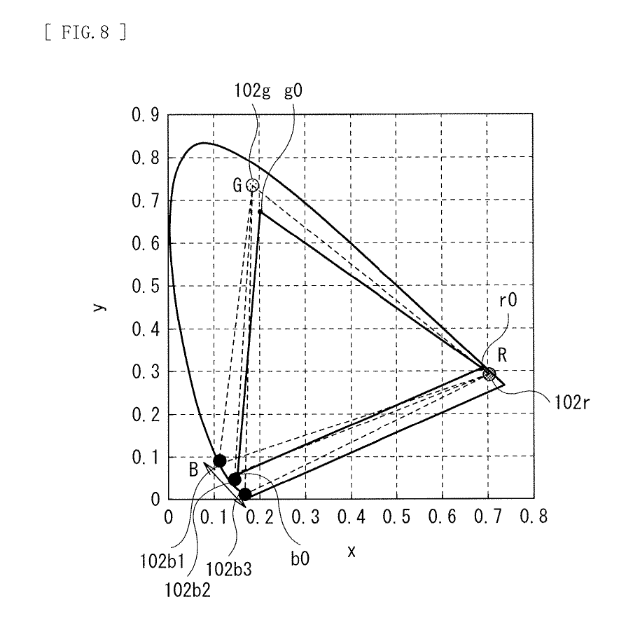

In the comparative example, the variations in the wavelengths as mentioned above causes variations in chromaticity points 102b1, 102b2, and 102b3 of the blue color, as illustrated in FIG. 8, for example. It is difficult to make a correction to uniformize the variations in the wavelengths. It is to be noted that in FIG. 8, a chromaticity point 102r of the red color and a chromaticity point 102g of the green color are illustrated, with no variations assumed. Moreover, chromaticity points r0, g0, and b0 are chromaticity points that correspond to respective design wavelengths of the red light emitting elements 101R, the green light emitting elements 101G, and the blue light emitting elements 101B.

In contrast, in this embodiment, the two kinds of the blue light emitting elements 10B1 and 10B2 are disposed, as the light emitting elements of the blue color, in each of the pixels P. This makes it possible to reduce influences on display by the variations in the wavelengths, by obtaining, in a manufacture phase, the composite ratio of the blue light emitting elements 10B1 and 10B2 and by correcting the drive signal on the basis of the composite ratio, as described above. In other words, it is possible to allow an apparent wavelength (the composite wavelength) of the blue color in each of the pixels P to be substantially uniform (to be uniformized).

FIG. 9 illustrates one example of the wavelengths of the respective blue light emitting elements 10B1 and 10B2 in the three adjacent pixels P1, P2, and P3. In the manufacture processes, in each of the pixels P1 to P3, the wavelengths of the blue light emitting elements 10B1 and 10B2 are measured. In one example, in the pixel P1, a wavelength b1a of the blue light emitting element 10B1 is 465 nm, whereas a wavelength b2a of the blue light emitting element 10B2 is 465 nm. In the pixel P2, a wavelength b1b of the blue light emitting element 10B1 is 470 nm, whereas a wavelength b2b of the blue light emitting element 10B2 is 460 nm. In the pixel P3, a wavelength b1c of the blue light emitting element 10B1 is 468 nm, whereas a wavelength b2c of the blue light emitting element 10B2 is 463 nm. It is to be noted that the wavelength b1a (465 nm), the wavelength b1b (470 nm), and the wavelength b1c (468 nm) are one example of the wavelengths that belong to the wavelength band Wb1 as mentioned above. The wavelength b2a (465 nm), the wavelength b2b (460 nm), and the wavelength b2c (463 nm) are one example of the wavelengths that belong to the wavelength band Wb2 as mentioned above.

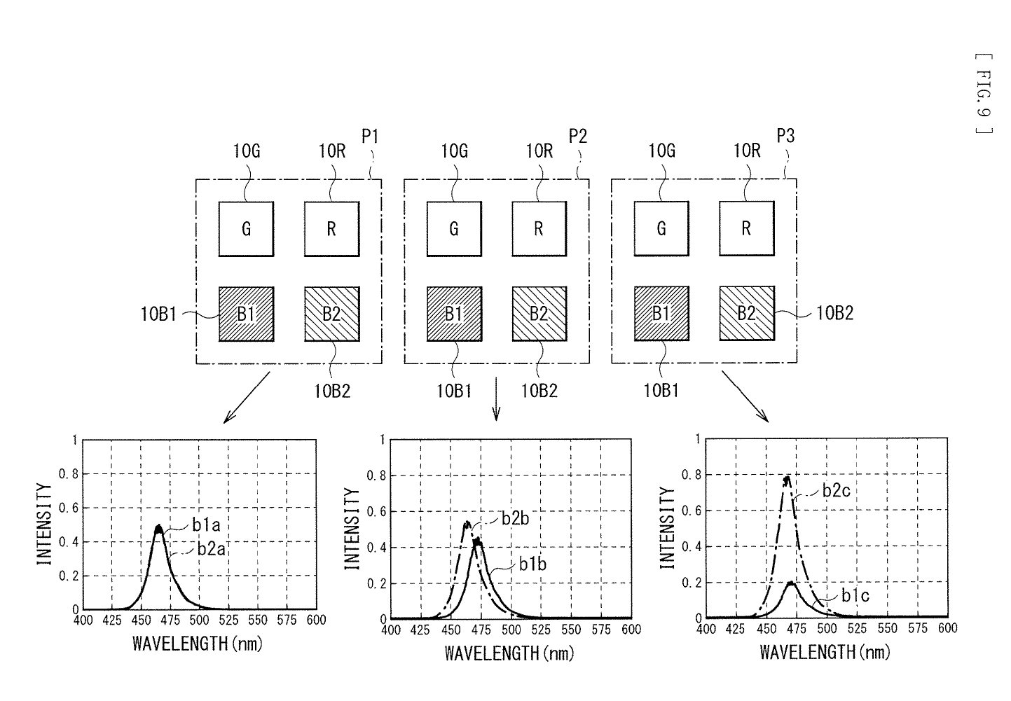

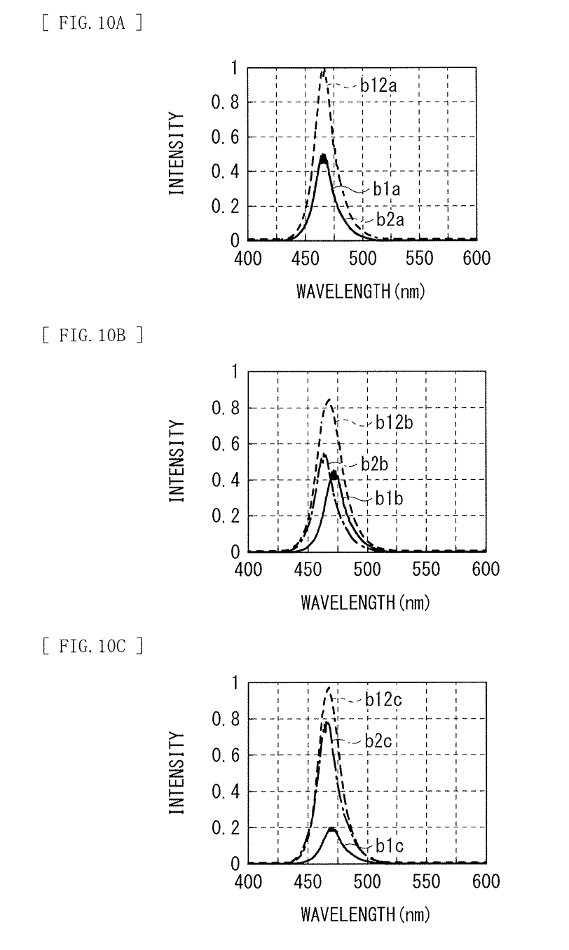

In the manufacture processes, on the basis of each of the wavelengths measured, the composite ratio to obtain the desired composite wavelength is calculated for each of the pixels P. For example, in a case where a target wavelength is 465 nm (the wavelengths of the blue color of all the pixels P are to be adjusted to 465 nm), the composite ratio may be set as follows. That is, in the pixel P1, as illustrated in FIG. 10A, for example, addition of the wavelengths b1a and b2a at a rate of 50% each (at a ratio of bla:b2a=0.5:0.5) makes it possible to obtain a composite wavelength b12a having an intensity peak in the vicinity of the wavelength of 465 nm. Moreover, in the pixel P2, as illustrated in FIG. 10B, for example, addition of the wavelengths b1b and b2b at rates of 55% and 45% respectively (at a ratio of blb:b2b=0.55:0.45) makes it possible to obtain a composite wavelength b12b having the intensity peak in the vicinity of the wavelength of 465 nm. Furthermore, in the pixel P3, as illustrated in FIG. 10C, for example, addition of the wavelengths b1c and b2c at rates of 80% and 20% respectively (at a ratio of b1c:b2c=0.8:0.2) makes it possible to obtain a wavelength bl2c having the intensity peak in the vicinity of the wavelength of 465 nm.

The composite ratio (the output ratio) for each of the pixels P thus calculated is held as the correction coefficient in the correction processor unit 300. The correction processor unit 300 corrects the drive signal for each of the pixels P, with the utilization of the correction coefficient. The drive signal is transmitted from the controller unit 400. Specifically, the correction processor unit 300 sets, in accordance with the correction coefficient, an output (the drive current) for each of the blue light emitting elements 10B1 and 10B2, in the drive signal for the blue color. The drive signal thus corrected is supplied to each of the pixels P by the driver unit 200, causing the LEDs of the respective colors to emit light in each of the pixels P. Picture display is performed by the additive color mixture of R, G, and B.

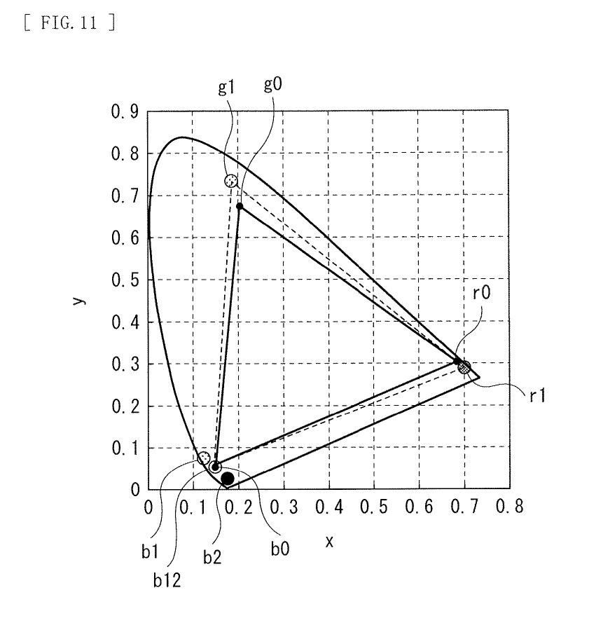

In this way, as illustrated in FIG. 11, the chromaticity point of the blue color in each of the pixels P may be dealt with, not as the chromaticity points b1 and b2 that correspond to the respective wavelengths of the blue light emitting elements 10B1 and 10B2, but as a chromaticity point b12 that corresponds to the composite wavelength of them. In other words, it is a chromaticity point r1 of the red light emitting element 10R, a chromaticity point g1 of the green light emitting element 10G, and the chromaticity point b12 corresponding to the composite wavelength of the blue color that contribute to the additive color mixture in each of the pixels P.

Accordingly, the two kinds of the blue light emitting elements 10B1 and 10B2 are disposed, in the single pixel P, as the light emitting elements for the blue color. The two kinds of the blue light emitting elements 10B1 and 10B2 have the peak wavelengths of the light emission in the different wavelength bands Wb1 and Wb2. This makes it possible to spuriously uniformize the variations in the wavelengths of the blue color (to provide apparent uniformization). As a result, it is possible to reduce the influence on the display by the variations in the wavelengths of the blue color.

As described, in this embodiment, the pixel P includes, as the light emitting elements of the blue color as one of the primary colors, the blue light emitting elements 10B1 and 10B2 having the peak wavelengths of the light emission in the different wavelength bands Wb1 and Wb2. Accordingly, it is possible to provide the picture display with the utilization of the composite wavelength of the wavelengths of the respective blue light emitting elements 10B1 and 10B2 as the wavelength of the blue color in the pixel P. Even in a case with the variations in the wavelengths of the blue color in the image surface due to the manufacture processes, it is possible to enhance the apparent wavelength uniformity. This leads to reduction in the influence on the display by the variations in the wavelengths, making it possible to represent the desired hues and brightness. Hence, it is possible to achieve enhancement in quality (image quality).

It is to be noted that in the forgoing first embodiment, the two kinds of the blue light emitting elements 10B1 and 10B2 are disposed in the pixel P, solely with attention to the variations in the wavelengths of the blue color. However, this technique may be also applied to variations in wavelengths of the red color and the green color, making it possible to obtain effects equivalent to those of the case of the blue color. Described later is layout in a case where the light emitting elements of the red color and the green color are disposed in two or more kinds each.

### Application Example

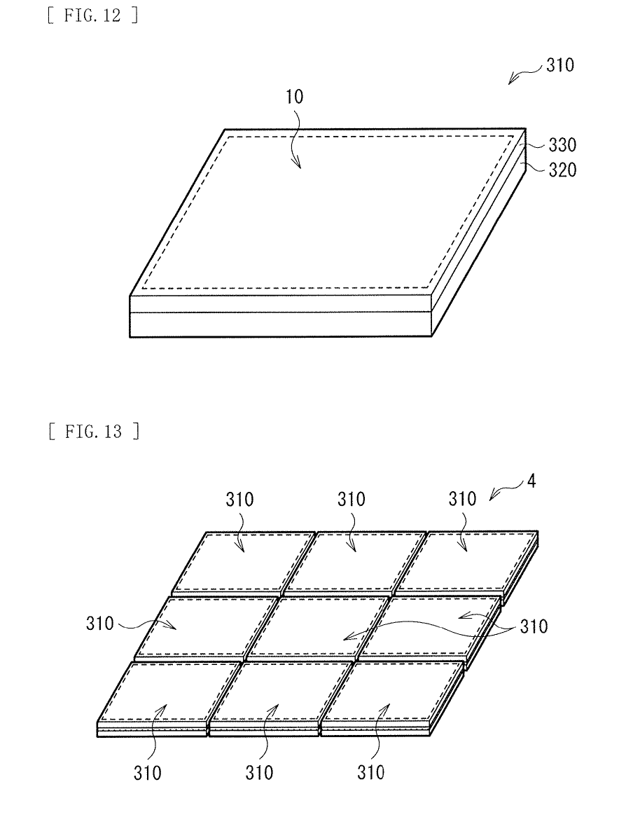

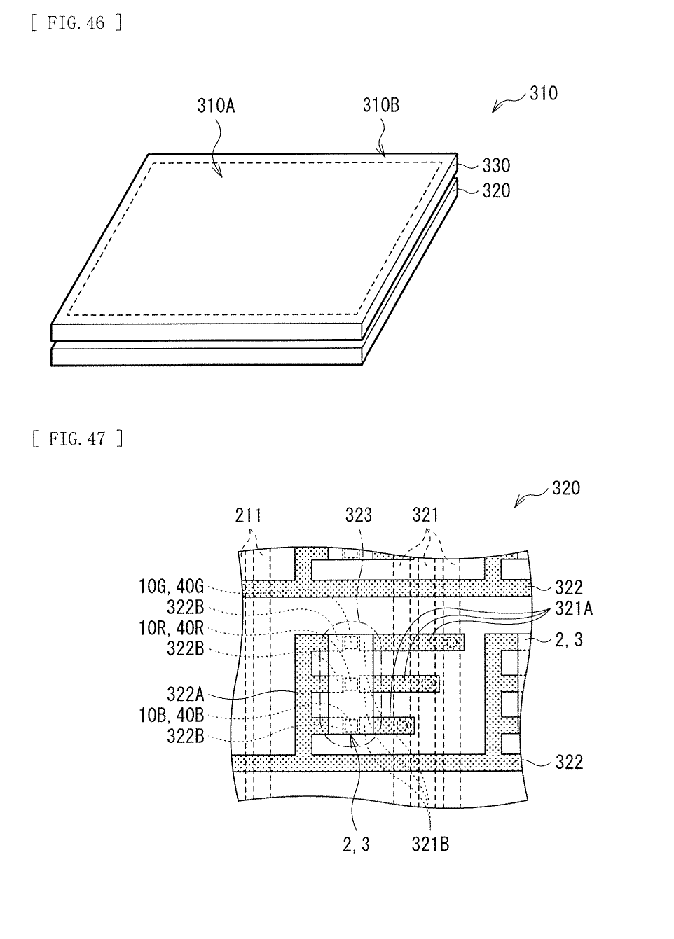

FIGS. 12 and 13 illustrate one example of an electronic apparatus according to an application example of the display apparatus 1 of the forgoing first embodiment. The display apparatus 1 may serve as a display unit 310 as illustrated in FIG. 12, and constitute a tiling device 4 as illustrated in FIG. 13. The display unit 310 is a combination of an element substrate 330 and a mounting substrate 320. The element substrate 330 includes the pixel array unit 100 as mentioned above. The tiling device 4 is a so-called LED display, with the LEDs utilized as the display pixels. The tiling device 4 includes a plurality of the display units 310 that are two-dimensionally disposed, and is suitably used as a large-sized display installed indoors or outdoors. Although details are described later, the tiling device 4 includes, for example, the display unit 310 as illustrated in FIG. 46 and a driver circuit (undepicted). The driver circuit drives the display unit 310.

In the following, description is given of modification examples of the forgoing first embodiment, and of other embodiments. It is to be noted that constituent elements similar to those of the forgoing first embodiment are denoted by same reference characters, and description thereof is omitted as appropriate.

### Modification Examples 1-1 and 1-2

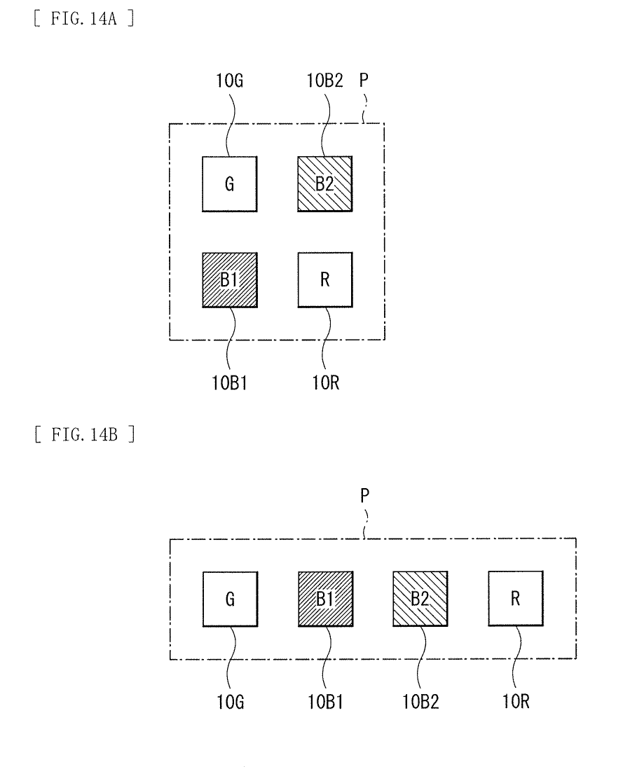

FIG. 14A is a schematic plan view of a configuration example of a pixel according to a modification example 1-1. FIG. 14B is a schematic plan view of a configuration example of a pixel according to a modification example 1-2. In the forgoing first embodiment, exemplified is a configuration in which the two blue light emitting elements 10B1 and 10B2 are disposed, in the pixel P, side by side along the row direction. However, the disposition of the blue light emitting elements 10B1 and 10B2 in the pixel P is not limited thereto. For example, as in the modification example 1-1 illustrated in FIG. 14A, the blue light emitting elements 10B1 and 10B2 may be disposed along an oblique direction in a 2×2 pixel arrangement. Moreover, although illustration is omitted, the blue light emitting elements 10B1 and 10B2 may be disposed along the column direction.

Furthermore, in the forgoing first embodiment, exemplified is a configuration in which the red light emitting element 10R, the green light emitting element 10G, and the blue light emitting elements 10B1 and 10B2 are disposed, in the pixel P, to form the 2×2 arrangement. However, the arrangement of the elements in the pixel P is not limited thereto. For example, as in the modification example 1-2 illustrated in FIG. 14B, the red light emitting element 10R, the green light emitting element 10G, and the blue light emitting elements 10B1 and 10B2 may be disposed in one row (to form a 1×4 arrangement). Moreover, although illustration is omitted, the red light emitting element 10R, the green light emitting element 10G, and the blue light emitting elements 10B1 and 10B2 may be disposed in one column (to form a 4×1 arrangement).

### Modification Examples 2-1 to 2-3

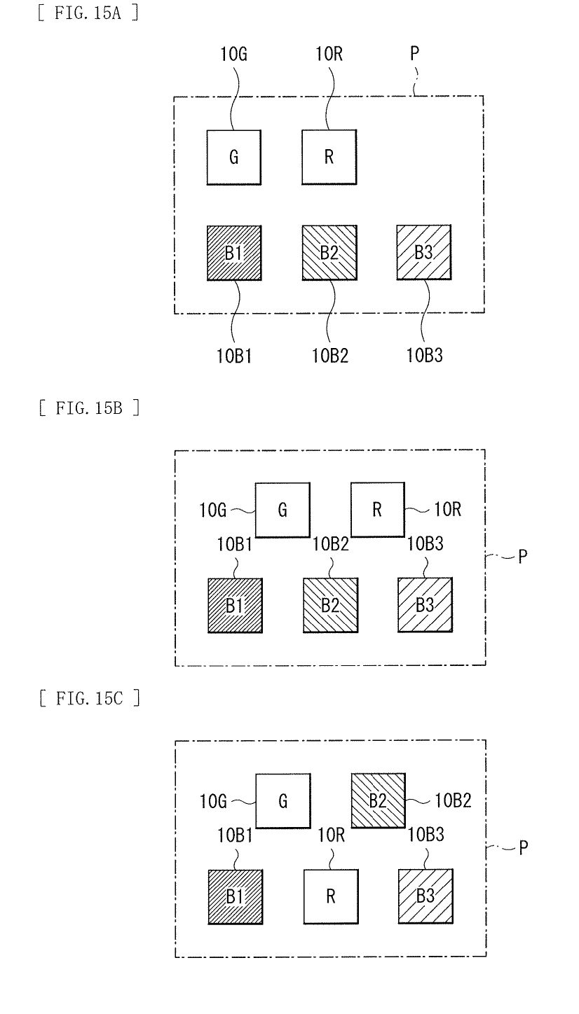

FIG. 15A is a schematic plan view of a configuration example of a pixel according to a modification example 2-1. FIG. 15B is a schematic plan view of a configuration example of a pixel according to a modification example 2-2. FIG. 15C is a schematic plan view of a configuration example of a pixel according to a modification example 2-3. In the forgoing first embodiment, exemplified is a configuration in which the blue light emitting elements 10B1 and 10B2 are disposed, in the pixel P, in two in total. However, the number (the kinds) of the blue light emitting elements disposed in the pixel P is not limited thereto.

For example, as in the modification example 2-1 illustrated in FIG. 15A, three blue light emitting elements 10B1 to 10B3 may be disposed in the pixel P. In this case, the blue light emitting element 10B3 has the peak wavelength of the light emission in the different wavelength band from the wavelength bands Wb1 and Wb2 of the blue light emitting elements 10B1 and 10B2. Moreover, the single red light emitting element 10R and the single green light emitting element 10G are disposed side by side in one row, whereas the three blue light emitting elements 10B1 to 10B3 are disposed side by side in a different row from the red light emitting element 10R and the green light emitting element 10G.

Furthermore, as in the modification example 2-2 illustrated in FIG. 15B, the red light emitting element 10R and the green light emitting element 10G may be shifted in position with respect to the three light emitting elements 10B1 to 10B3, so as to provide layout having symmetry.

In addition, as in the modification example 2-3 illustrated in FIG. 15C, the three blue light emitting elements 10B1 to 10B3 may be disposed over two rows in the pixel P. In other words, the red light emitting element 10R, the green light emitting element 10G, and the blue light emitting elements 10B1 to 10B3 may be disposed in a mixture in each row in the pixel P.

### Modification Examples 3-1 to 3-3

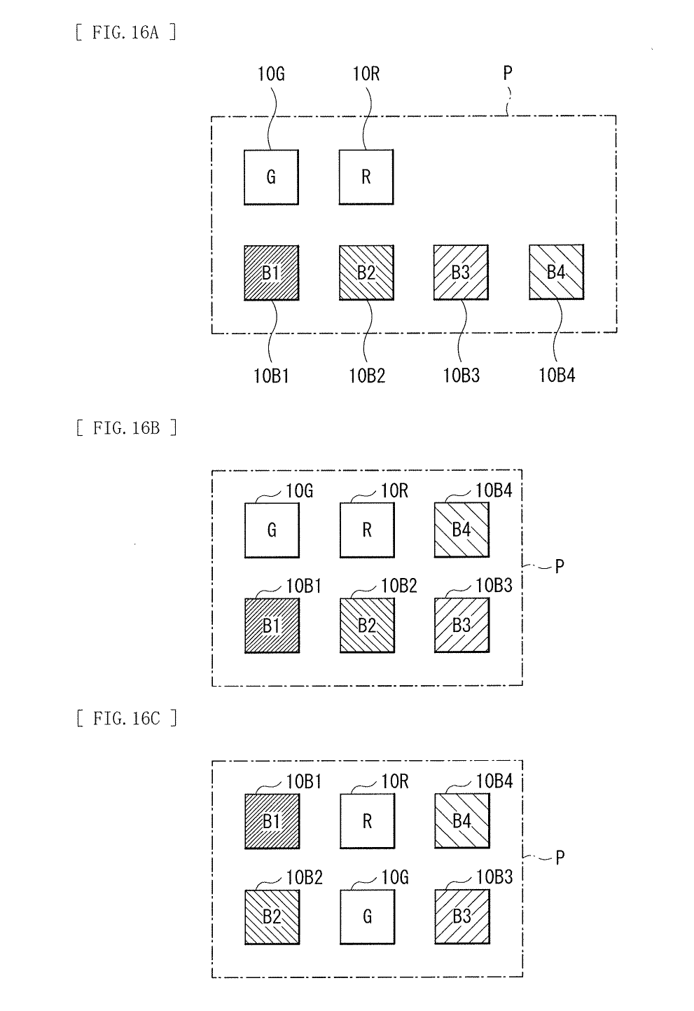

FIG. 16A is a schematic plan view of a configuration example of a pixel according to a modification example 3-1. FIG. 16B is a schematic plan view of a configuration example of a pixel according to a modification example 3-2. FIG. 16C is a schematic plan view of a configuration example of a pixel according to a modification example 3-3. As in the modification examples 3-1 to 3-3, four blue light emitting elements 10B1 to 10B4 may be disposed in the pixel P. In this case, the blue light emitting element 10B4 has the peak wavelength of the light emission in a different wavelength band from the wavelength bands of the respective blue light emitting elements 10B1 to 10B3.

In the modification example 3-1 illustrated in FIG. 16A, the single red light emitting element 10R and the single green light emitting element 10G are disposed side by side in one row, whereas the four blue light emitting elements 10B1 to 10B3 are disposed side by side in a different row from the red light emitting element 10R and the green light emitting element 10G.

In the modification example 3-2 illustrated in FIG. 16B, one of the four blue light emitting elements 10B1 to 10B4 (here, the blue light emitting element 10B4) is shifted in position to the row in which the red light emitting element 10R and the green light emitting element 10G are disposed. The red light emitting element 10R, the green light emitting element 10G, and the blue light emitting elements 10B1 to 10B4 are disposed in two rows and three columns as a whole (to form a 2×3 arrangement).

In the modification example 3-3 illustrated in FIG. 16C, in the configuration in which the red light emitting element 10R, the green light emitting element 10G, and the blue light emitting element 10B1 to 10B4 are disposed in the two rows and the three columns as the whole, the red light emitting element 10R and the green light emitting element 10G form a central row. The blue light emitting elements 10B1 to 10B4 are disposed on both sides of the red light emitting element 10R and the green light emitting element 10G.

### Modification Examples 4-1 and 4-2

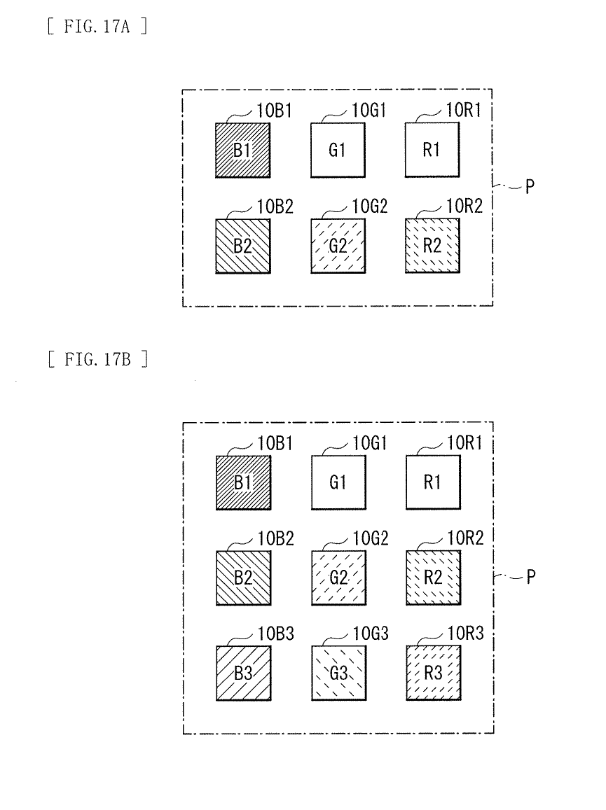

FIG. 17A is a schematic plan view of a configuration example of a pixel according to a modification example 4-1. FIG. 17B is a schematic plan view of a configuration example of a pixel according to a modification example 4-2. In the forgoing first embodiment, exemplified is a configuration in which the red light emitting element 10R and the green light emitting element 10G are disposed one each in the pixel P. However, the number (the kinds) of the red light emitting element and the green light emitting element disposed in the pixel P is not limited thereto.

For example, as in the modification example 4-1 illustrated in FIG. 17A, two red light emitting elements 10R1 and 10R2 may be disposed, in the pixel P, as light emitting elements of the red color. The two red light emitting elements 10R1 and 10R2 have the peak wavelengths of the light emission in the different wavelength bands. Moreover, two green light emitting elements 10G1 and 10G2 may be disposed, in the pixel P, as light emitting elements of the green color. The two green light emitting elements 10G1 and 10G2 have the peak wavelengths of the light emission in the different wavelength bands. This makes it possible to reduce the influences on the display by the variations in the wavelengths in a similar technique to the forgoing, with respect to not only blue but also red and green.

Moreover, in another alternative configuration, two or more kinds of light emitting elements may be disposed solely for the red color or the green color out of the three primary colors of R, G, and B, so as to allow for the uniformization of the variations in the wavelengths of the red color or the green color, instead of the blue color. Furthermore, two or more kinds of light emitting elements may be disposed for two or more (two or three) primary colors out of the three primary colors of R, G, and B, so as to allow for the uniformization of the variations in the wavelengths in the two or more primary colors. As described, the primary color as a target of the correction may be optimally selected. Moreover, in a case where the two or more primary colors are selected, there is no limitation on a combination of their wavelengths. However, because the blue color has highest visibility to the human eye, it is possible to produce more significant effects by making the correction in the blue color in particular, in consideration of the variations in the wavelengths as mentioned above.

In addition, as illustrated in FIG. 17B, light emitting elements in three kinds in total may be disposed, in the pixel P, as the light emitting elements of each of the red color, the green color, and the blue color. In this example, red light emitting elements 10R1 to 10R3, green light emitting elements 10G1 to 10G3, and the blue light emitting elements 10B1 to 10B3 are each disposed side by side along the column direction.

### Modification Examples 5-1 and 5-2

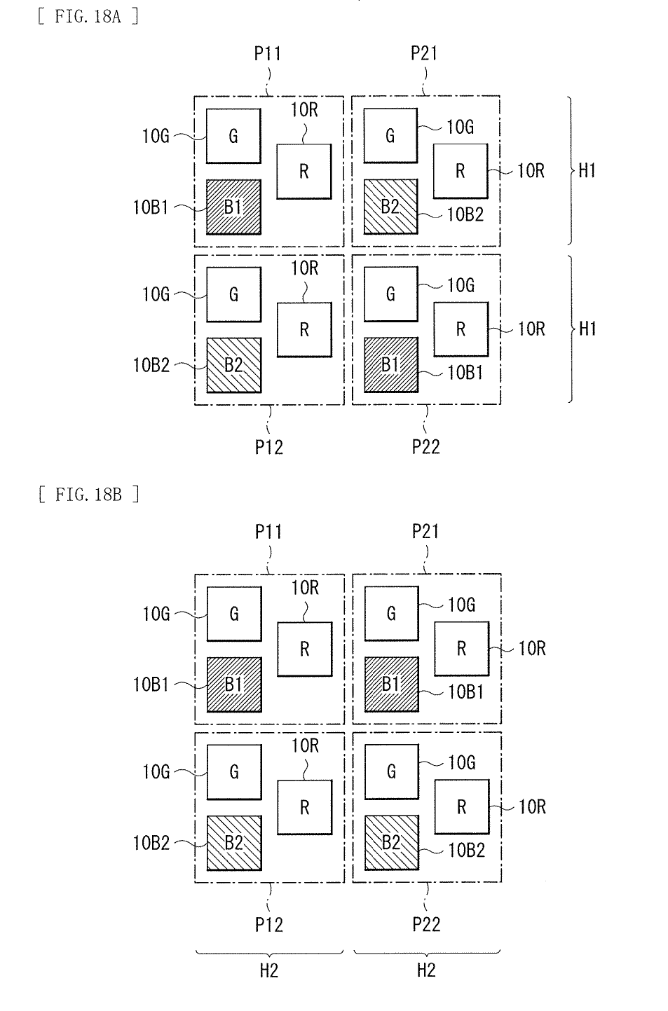

FIG. 18A is a schematic plan view of a configuration example of pixels according to a modification example 5-1. FIG. 18B is a schematic plan view of a configuration example of pixels according to a modification example 5-2. In the forgoing first embodiment and the modification examples 1 to 4, described are configurations in which the two or more light emitting elements are disposed, in the single pixel P, as the light emitting elements of the blue color (or the light emitting elements of the red color and the green color). The two or more light emitting elements have the peak wavelengths of the light emission in the different wavelength bands. However, the light emitting elements of the blue color may be disposed not in the pixel P but in a pixel group including a plurality of the pixels P (over the plurality of the pixels P). In this case, the correction coefficient regarding the output ratio of the light emitting elements of the blue color is set for each pixel group.

For example, as in the modification example 5-1 illustrated in FIG. 18A, the blue light emitting elements 10B1 and 10B2 as described above may be disposed in a pixel group H1. The pixel group H1 includes two pixels P11 and P21 (or pixels P12 and P22) in adjacency along the row direction. In this example, the blue light emitting elements 10B1 and 10B2 are respectively disposed in the pixels P11 and P21. Moreover, the blue light emitting elements 10B2 and 10B1 are respectively disposed in the pixels P12 and P22.

Moreover, as in the modification example 5-2 illustrated in FIG. 18B, the blue light emitting elements 10B1 and 10B2 as described above may be disposed in a pixel group H2. The pixel group H2 includes the two pixels P11 and P12 (or the pixels P21 and P22) in adjacency along the column direction. In this example, the blue light emitting elements 10B1 and 10B2 are respectively disposed in the pixels P11 and P12. Moreover, the blue light emitting elements 10B1 and 10B2 are respectively disposed in the pixels P21 and P22.

### Modification Examples 6-1 and 6-2

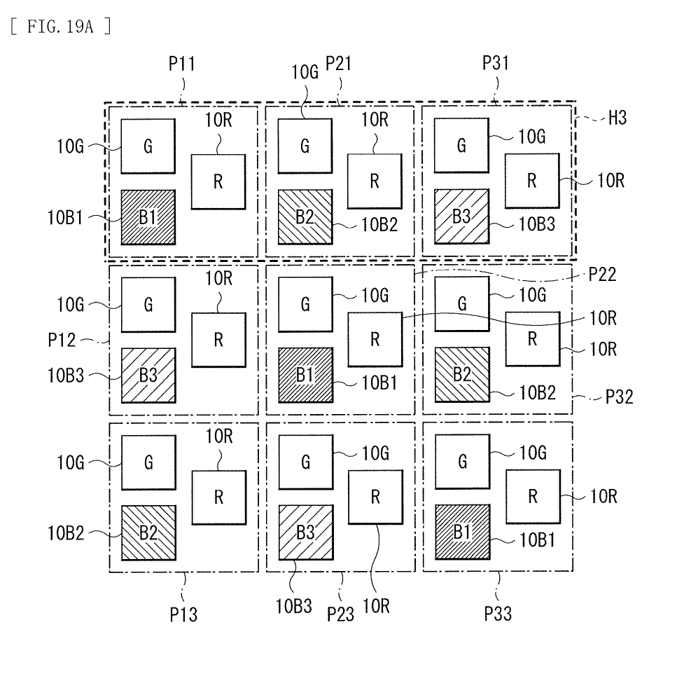

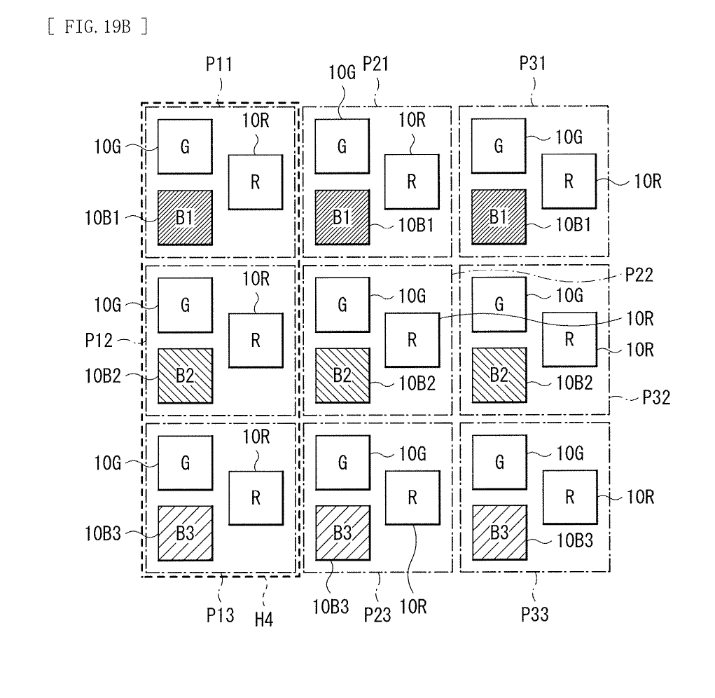

FIG. 19A is a schematic plan view of a configuration example of pixels according to a modification example 6-1. FIG. 19B is a schematic plan view of a configuration example of pixels according to a modification example 6-2. In the forgoing modification examples 5-1 and 5-2, exemplified are configurations in which the blue light emitting elements 10B1 and 10B2 are disposed in two in total in the single pixel group. However, the number (the kinds) of the blue light emitting elements disposed in the pixel group is not limited thereto.

For example, as in the modification example 6-1 illustrated in FIG. 19A, the blue light emitting elements 10B1 to 10B3 as described above may be disposed in a pixel group H3. The pixel group H3 includes three pixels P11, P21, and P31 (or pixels P12, P22, and P32, or pixels P13, P23, and P33) in adjacency along the row direction. In this example, the blue light emitting elements 10B1, 10B2, and 10B3 are respectively disposed in the pixel P11, P21, and P31. Moreover, the blue light emitting elements 10B3, 10B1, and 10B2 are respectively disposed in the pixels P12, P22, and P32. The blue light emitting elements 10B2, 10B3, and 10B1 are respectively disposed in the pixels P13, P23, and P33. It is to be noted that the arrangement of the blue light emitting elements 10B1 to 10B3 may be either different or the same in each pixel group H3.

Moreover, as in the modification example 6-2 illustrated in FIG. 19B, the blue light emitting elements 10B1 to 10B3 as described above may be disposed in a pixel group H4. The pixel group H4 includes the three pixels P11, P12, and P13 (or the pixels P21, P22, and P23, or the pixels P31, P32, and P33) in adjacency along the column direction. In this example, the blue light emitting elements 10B1, 10B2, and 10B3 are respectively disposed in the pixels P11, P12, and P13. Moreover, the blue light emitting elements 10B1, 10B2, and 10B3 are respectively disposed in the pixels P21, P22, and P23. The blue light emitting elements 10B1, 10B2, and 10B3 are respectively disposed in the pixel P31, P32, and P33. It is to be noted that the arrangement of the blue light emitting elements 10B1 to 10B3 may be either different or the same in each pixel group H4.

### Modification Examples 7-1 to 7-3

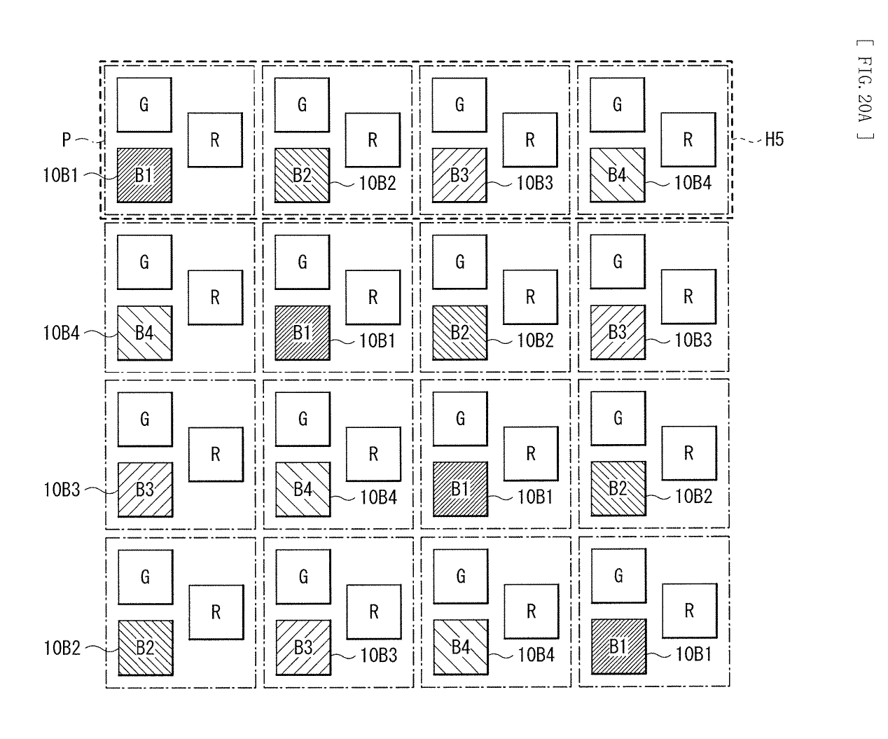

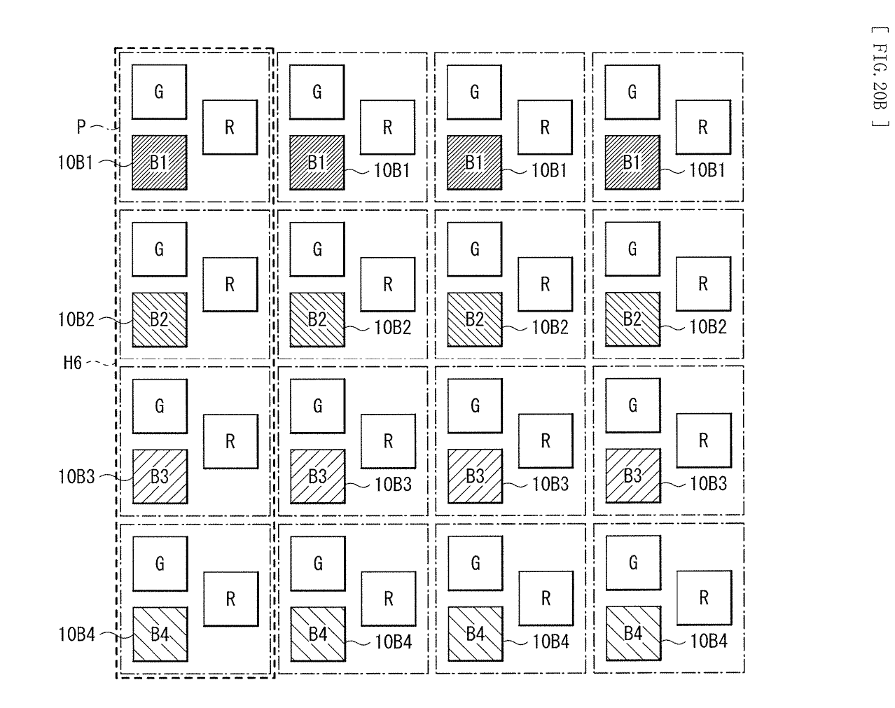

FIG. 20A is a schematic plan view of a configuration example of pixels according to a modification example 7-1. FIG. 20B is a schematic plan view of a configuration example of pixels according to a modification example 7-2. FIG. 20C is a schematic plan view of a configuration example of pixels according to a modification example 7-3. In the forgoing modification examples 5-1 and 5-2, exemplified are configurations in which the blue light emitting elements 10B1 and 10B2 are disposed in two in total in the single pixel group. However, the number (the kinds) of the blue light emitting elements disposed in the pixel group is not limited thereto.

For example, as in the modification example 7-1 illustrated in FIG. 20A, the blue light emitting elements 10B1 to 10B4 as described above may be disposed in a pixel group H5. The pixel group H5 includes the four pixels P in adjacency along the row direction. It is to be noted that the arrangement of the blue light emitting elements 10B1 to 10B4 may be either different or the same in each pixel group H5.

Moreover, as in the modification example 7-2 illustrated in FIG. 20B, the blue light emitting elements 10B1 to 10B4 as described above may be disposed in a pixel group H6. The pixel group H6 includes the four pixels P in adjacency along the column direction. It is to be noted that the arrangement of the blue light emitting elements 10B1 to 10B4 may be either different or the same in each pixel group H6.

Furthermore, as in the modification example 7-3 illustrated in FIG. 20C, the blue light emitting elements 10B1 to 10B4 as described above may be disposed in a pixel group H7. The pixel group H7 includes the four pixels in adjacency in the two rows and the two columns (to form the 2×2 arrangement). It is to be noted that the arrangement of the blue light emitting elements 10B1 to 10B4 may be either different or the same in each pixel group H7.

### Modification Example 8

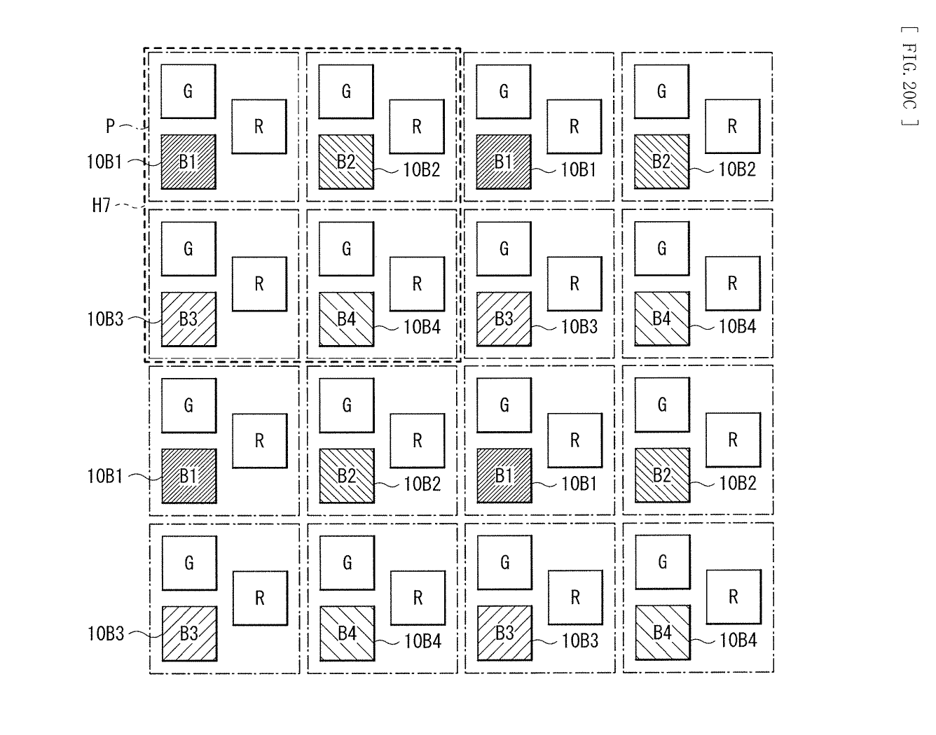

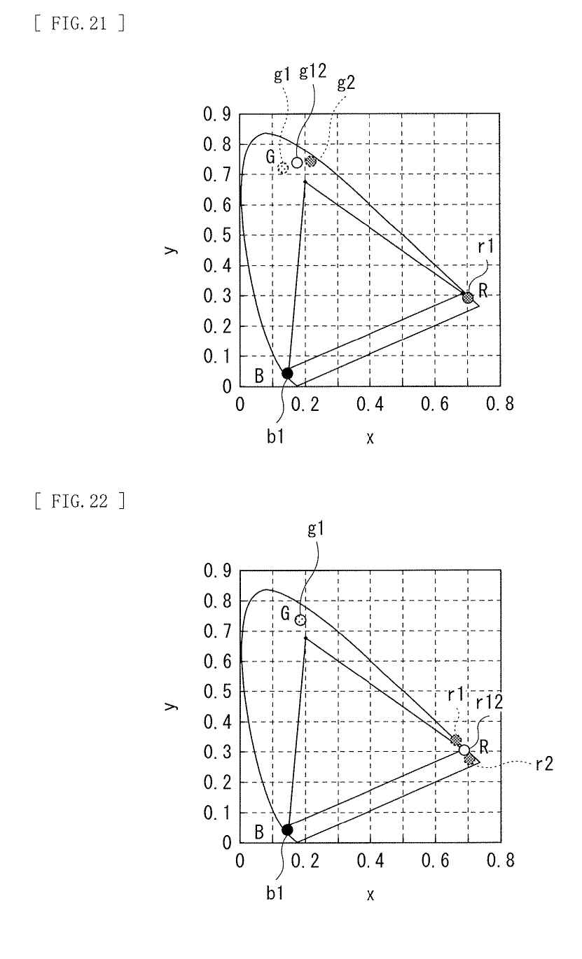

FIG. 21 is a characteristic diagram provided for description of correction of a G wavelength according to a modification example 8. FIG. 22 is a characteristic diagram provided for description of correction of an R wavelength according to the modification example 8. Adopting, in the pixel P, the configuration described in the forgoing modification examples 4-1 and 4-2 makes it possible to reduce the influence on the display by the variations in the wavelengths of the red color and the green color. This leads to further advantages in the enhancement in the image quality.

In a case where the green color out of the three primary colors of R, G, and B serves as the target of the correction, as illustrated in FIG. 2, it is possible to perform the additive color mixture in which the chromaticity point of the green color of the pixel P is not chromaticity points g1 and g2 that correspond to the wavelengths of the respective green light emitting elements, but a chromaticity point g12 that corresponds to the composite wavelength of them. Moreover, in a case where the red color serves as the target of the correction, as illustrated in FIG. 22, it is possible to perform the additive color mixture in which the chromaticity point of the red color of the pixel P is not chromaticity points r1 and r2 that correspond to the wavelengths of the respective red light emitting elements, but a chromaticity point r12 that corresponds to the composite wavelength of them. It is to be noted that as described above, the two or more primary colors out of the three primary colors of R, G, and B may serve as the targets of the correction.

### Modification Example 9

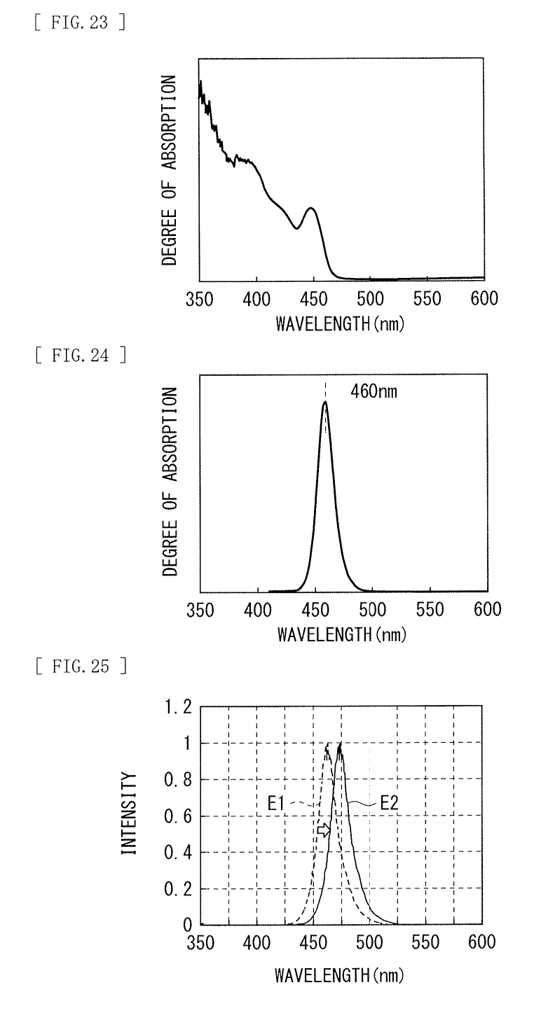

FIG. 23 is a characteristic diagram provided for description of one example of a QD (quantum dot) filter according to a modification example 9. In the forgoing example embodiments, in order to cope with the variations in the wavelengths of the primary colors, the two or more kinds of the light emitting elements are disposed in the pixel P or the pixel group. This allows for reduction in color unevenness due to the variations in the wavelengths. However, as in this modification example, the variations in the wavelengths may be reduced with the utilization of a predetermined wavelength conversion filter. In other words, in this modification example, disposing the wavelength conversion filter such as the QD filter in the pixel array unit 100 makes it possible to provide an output at a wavelength in accordance with absorption characteristics and light emission characteristics of the QD filter. Hence, it is possible to reduce the in-plane variations in the wavelengths.

For example, the QD filter may be utilized that has an absorption spectrum as illustrated in FIG. 23 and a light emission spectrum as illustrated in FIG. 24. The light emission spectrum has an intensity peak in the vicinity of 460 nm. Examples of materials that exhibit such characteristics include a fluorescent substance that utilizes CdS and ZnS. Thus, as illustrated in FIG. 25, for example, part of light emission of short wavelengths (E1) out of the blue color is absorbed, and converted into light emission of long wavelengths (E2). Utilizing the wavelength conversion filter makes it possible to reduce the in-plane variations in the wavelengths, and to uniformize the wavelengths, even in a case with the large variations in the wavelengths.

### Second Embodiment

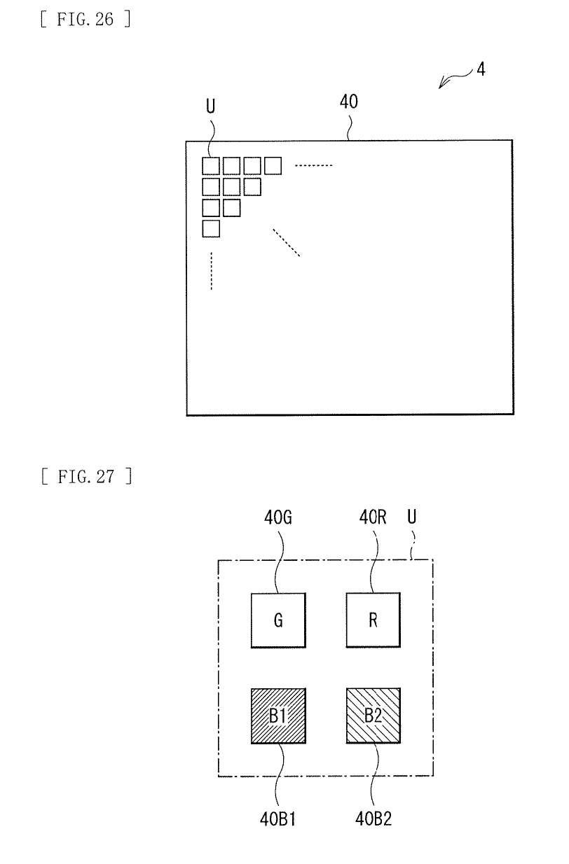

FIG. 26 illustrates a configuration of a main part of an illumination apparatus (an illumination apparatus 5) according to a second embodiment of the disclosure. The illumination apparatus 5 includes an element array unit 500. The element array unit 500 is so constituted as to include, for example, a plurality of units U that are two-dimensionally disposed. In the single unit U, disposed are the light emitting elements that emit light of the two or more primary colors (here, the three primary colors of R, G, and B). Examples of the light emitting elements include the light emitting diodes (LEDs) that emit the color light in the red (R), the green (G), and the blue (B). The red LED (the red light emitting element) is made of, for example, the AlGaInP-based materials. The green LED (the green light emitting element) and the blue LED (the blue light emitting element) are made of, for example, the AlGaInN-based materials. In the element array unit 500, the unit U is driven by an undepicted driver unit, and the luminance of the LEDs in each unit U is adjusted. Thus, illumination light in, for example, a white color is produced.

FIG. 27 illustrates a configuration example of the unit U. As illustrated, in the single unit U, disposed are a green light emitting element 40G, a red light emitting element 40R, and two kinds of blue light emitting elements 40B1 and 40B2, as with the pixel P according to the forgoing example embodiments. Moreover, in the unit U, the red light emitting element 40R, the green light emitting element 40G, and the blue light emitting elements 40B1 and 40B2 are disposed in the two rows and the two columns as a whole (to form the 2×2 arrangement). The blue light emitting elements 40B1 and 40B2 are disposed side by side along the row direction (the right-left direction in the figure). The blue light emitting elements 40B1 and 40B2 have the peak wavelengths of the light emission in the different wavelength bands from each other. The blue light emitting elements 40B1 and 40B2 correspond to one specific example of the “first light emitting element” and the “second light emitting element” in the disclosure.

As described, in the illumination apparatus 5, the single unit U includes the blue light emitting elements 40B1 and 40B2, as the light emitting elements of the blue color as one of the primary colors. The blue light emitting elements 40B1 and 40B2 have the peak wavelengths of the light emission in the different wavelength bands. Accordingly, at the time of the light emission, the correction as mentioned above makes it possible to utilize the composite wavelength of the wavelengths of the respective blue light emitting elements 40B1 and 40B2, as the wavelength of the blue color in the unit U. It is possible to enhance the apparent wavelength uniformity even in the case where the wavelength of the blue color varies in the image surface due to the manufacture processes, for example. This leads to the reduction in the influences on the illumination light by the variation in the wavelengths, making it possible to represent the desired hues and brightness. Hence, it is possible to achieve the enhancement in the quality (illumination quality).

It is to be noted that the blue light emitting elements 40B1 and 40B2 as described above may be disposed in the single unit U as described above, or alternatively, the blue light emitting elements 40B1 and 40B2 may be disposed in a unit group. The unit group includes the two or more adjacent units U.

### 7. Third Embodiment

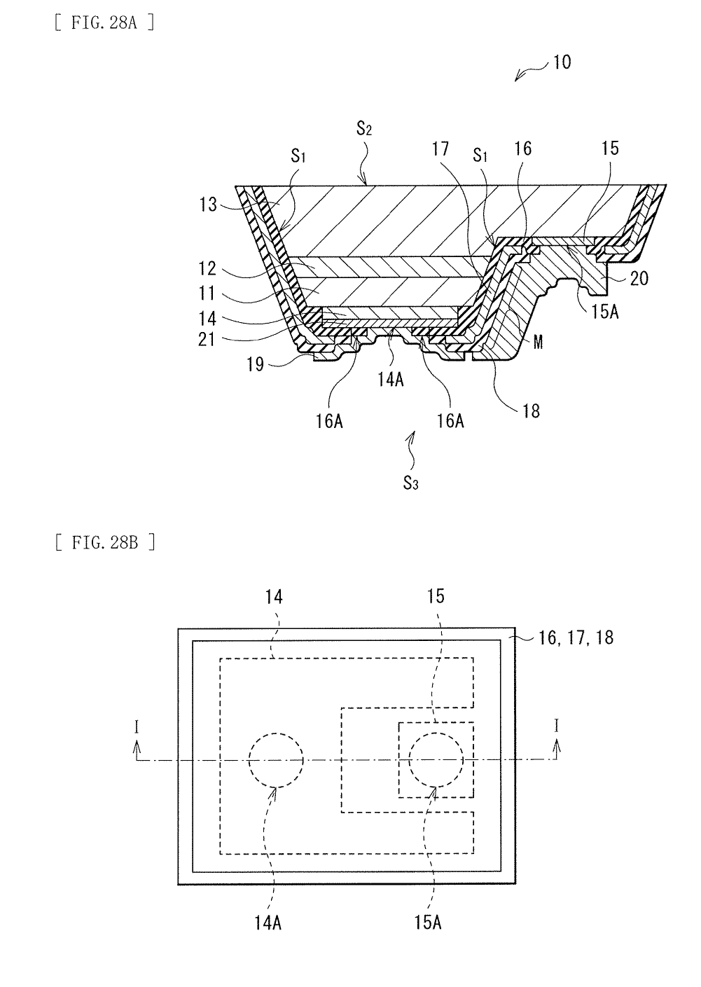

FIG. 28A illustrates a cross-sectional configuration of a light emitting element (a light emitting element 10) that serves as one example of, for example, the blue light emitting elements 10B1 and 10B2, the green light emitting element 10G, the red light emitting element 10R, the blue light emitting elements 40B1 and 40B2, the green light emitting element 40G, and the red light emitting element 40R utilized in the display apparatus (e.g., the display apparatus 1) and the illumination apparatus (e.g., the illumination apparatus 5). FIG. 28B illustrates a plan configuration of the light emitting element 10 illustrated in FIG. 28A. It is to be noted that FIG. 28A illustrates a cross-section along a line I-I of the light emitting element 10 illustrated in FIG. 28B. The light emitting element 10 is an LED chip of a Flip-Chip structure, and is utilized as, for example, the blue light emitting element 10B, the green light emitting element 10G, and the red light emitting element 10R disposed in the display pixel (the pixel P) of the display apparatus 1 as described above.

The light emitting element 10 has a structure in which a first conductive type layer 11, an active layer 12, and a second conductive type layer 13 constitutes a semiconductor layer, and a part of the semiconductor layer forms a mesa part M of a columnar shape. The part of the semiconductor layer includes a part of the second conductive type layer 13, the first conductive type layer 11, and the active layer 12. A first electrode 14 is provided on an upper surface of the mesa part M (a surface of the first conductive type layer 11). An upper surface of the second conductive type layer 13 (an opposite surface to the mesa part M out of the semiconductor) serves as a light extraction surface S₂. Out of the semiconductor layer, the first conductive type layer 11 is provided with the first electrode 14. The semiconductor layer has a flat surface in a base of the mesa part M. The second conductive type layer 13 is exposed in the flat surface. A second electrode 15 is provided on a part of the flat surface. In this embodiment, the second electrode 15 is provided with a larger thickness than the first electrode 14, and has a configuration in which the light extraction surface S₂ is so adjusted as to be, for example, substantially parallel to a mounting substrate of the light emitting element 10. It is to be noted that FIGS. 28A and 28B schematically illustrate the configuration of the light emitting element 10, and may be different in dimensions and shapes from reality.

### 7-1. Configuration of Light Emitting Element

The light emitting element 10 is a solid light emitting element that emits light of a predetermined wavelength body through an upper surface (the light extraction surface S₂). To be specific, the light emitting element 10 is an LED (Light Emitting Diode) chip. The LED chip refers to those in a cut-out state from a wafer utilized in crystal growth, instead of those of a package type that are covered with, for example, a molded resin. The LED chip has a size of, for example, 5 μm to 100 mm both inclusive, and is what is called a micro LED. A plan shape of the LED chip is, for example, a substantially square shape. The LED chip has a flake-like shape. An aspect ratio (height/width) of the LED chip is, for example, equal to or larger than 0.1 and smaller than 1.

As described, the light emitting element 10 includes the semiconductor layer. The semiconductor layer includes a stack of the first conductive type layer 11, the active layer 12, and the second conductive type layer 13 in the order, with the second conductive type layer 13 serving as the light extraction surface S₂ (a second surface). The semiconductor layer is provided with the mesa part M of the columnar shape. The mesa part M includes the first conductive type layer 11 and the active layer 12. The semiconductor layer includes a shoulder on a surface confronted with the light extraction surface S₂. The shoulder includes a projection and a recess. The first conductive type layer 11 is exposed in the projection. The second conductive type layer 13 is exposed in the recess. In this embodiment, the surface that is confronted with the light extraction surface S₂ and includes the projection and the recess is referred to as a lower surface S₃ (a first surface). The first electrode 14 and the second electrode 15 are each provided on the lower surface S₃. The first electrode 14 is electrically coupled to the first conductive type layer 11, whereas the second electrode 15 is electrically coupled to the second conductive type layer 13. Specifically, the first electrode 14 is provided on the first conductive type layer 11 that constitutes the projection of the first surface. The second electrode 15 is provided on the second conductive type layer 13 that constitutes the recess of the second surface.

As illustrated in FIG. 28A, for example, a side surface S₁ of the light emitting element 10 (specifically, the semiconductor layer) constitutes an inclined surface that crosses a stacking direction, as with the mesa part M. Thus, making the mesa part M and the side surface S₁ tapered makes it possible to enhance efficiency in light extraction through the light extraction surface S₂. Moreover, as illustrated in FIGS. 28A and 28B, the light emitting element 10 according to this embodiment includes a stacked body including a first insulating layer 16, a metal layer 17, and a second insulating layer 18. The stacked body is a layer provided from the side surface S₁ of the semiconductor layer, in confronted relation to the light extraction surface S₂, to a mounting surface (the lower surface S₃) in mounting the light emitting element 10 on the substrate. The stacked body provided on the lower surface S₃ (specifically, the first insulating layer 16) is provided over outer edges of surfaces of the first electrode 14 and the second electrode 15. In other words, the first electrode 14 and the second electrode 15 respectively include exposed surfaces 14A and 15A that are free from coverage with the stacked body. The exposed surfaces 14A and 15A are respectively provided with pad electrodes 19 and 20 as lead-out electrodes. In this embodiment, a film thickness of the pad electrode 20 as the lead-out electrode of the second electrode 15 is larger than that of the pad electrode 19. This leads to adjustment of inclination caused by the shape of the light emitting element 10.

In the following, description is given of each member that constitutes the light emitting element 10.

As to the first conductive type layer 11, the active layer 12, and the second conductive type layer 13 that constitute the semiconductor layer, materials are selected as appropriate in accordance with light of desired wavelength bands. Specifically, in a case where light of a green band or light of a blue band is to be obtained, it is preferable that for example, InGaN-based semiconductor materials be utilized. In a case where light of a red band is to be obtained, it is preferable that for example, AlGaInP-based semiconductor materials be utilized.

The first electrode 14 is in contact with the first conductive type layer 11, and is electrically coupled to the first conductive type layer 11. In other words, the first electrode 14 is in ohmic-contact with the first conductive type layer 11. The first electrode 14 is a metal electrode, and is constituted as a multi-layered body of, for example, titanium (Ti)/platinum (Pt)/gold (Au) or an alloy of gold and germanium (Au—Ge)/nickel (Ni)/Au. In addition, the first electrode 14 may be so constituted as to include a metal material having high reflectivity such as silver (Ag) and aluminum (Al).

The second electrode 15 is in contact with the second conductive type layer 13, and is electrically coupled to the second conductive type layer 13. In other words, the second electrode 15 is in ohmic-contact with the second conductive type layer 13. The second electrode 15 is a metal electrode, and is constituted as the multi-layered body of, for example, Ti/Pt/Au or Au—Ge/Ni/Au, as with the first electrode. The second electrode 15 may so constituted as to further include the metal material having the high reflectivity such as Ag and Al. The first electrode 14 and the second electrode 15 may each be constituted by a single electrode, or alternatively, the first electrode 14 and the second electrode 15 may each be constituted by a plurality of electrodes.

The stacked body is a layer provided from the side surface S₁ of the semiconductor layer to the lower surface S₃. The stacked body has a configuration in which the first insulating layer 16, the metal layer 17, and the second insulating layer 18 are stacked in the order on the semiconductor layer. The stacked body covers at least an entirety of the side surface S₁, and is provided from a confronted region with the side surface S₁ to a part of a confronted region with the first electrode 14. It is to be noted that the first insulating layer 16, the metal layer 17, and the second insulating layer 18 are each a thin layer, and are each formed by a thin film forming process such as CVD, evaporation, and sputtering. That is, out of the stacked body, at least the first insulating layer 16, the metal layer 17, and the second insulating layer 18 are not formed by a thick film forming process such as spin coating, by resin molding, or by potting.

The first insulating layer 16 forms electrical insulation between the metal layer 17 and the semiconductor layer. The first insulating layer 16 is provided from an end of the side surface S₁ on side on which the base of the mesa part M is disposed, to the outer edge of the surface of the first electrode 14. In other words, the first insulating layer 16 is provided in contact with an entirety of the side surface S₁, and is further provided in contact with the outer edge of the surface of the first electrode 14. Examples of materials of the first insulating layer 16 include a transparent material with respect to light emitted from the active layer 12, e.g., SiO₂, SiN, Al₂O₃, TiO₂, and TiN. A thickness of the first insulating layer 16 is, for example, about 0.1 μm to 1 μm both inclusive, and is a substantially uniform thickness. It is to be noted that the first insulating layer 16 may have non-uniformity in thickness caused by manufacture errors.

The metal layer 17 shields or reflects the light emitted from the active layer 12. The metal layer 17 is provided in contact with a surface of the first insulating layer 16. The metal layer 17 is provided, in the surface of the first insulating layer 16, from an end on side on which the light extraction surface S₂ is disposed, to a position slightly retreating from an end on side on which the first electrode 14 is disposed. In other words, the first insulating layer 16 includes an exposed surface 16A in a confronted part with the first electrode 14. The exposed surface 16A is free from coverage with the metal layer 17.

An end of the metal layer 17 on the side on which the light extraction surface S₂ is disposed is provided on a same surface as the end of the first insulating layer 16 on the side on which the light extraction surface S₂ is disposed (a same surface as the light extraction surface S₂). Meanwhile, an end of the metal layer 17 on the side on which the first electrode 14 is disposed is provided in a confronted region with the first electrode 14, and is superposed on a part of the metal layer 17, with the first insulating layer 16 in between. That is, the metal layer 17 is insulated and separated (electrically separated) by the first insulating layer 16 from the semiconductor layer, the first electrode 14, and the second electrode 15.

There is a gap between the end of the metal layer 17 on the side on which the first electrode 14 is disposed and the metal layer 17. The gap is as large as the thickness of the first insulating layer 16. However, the gap as mentioned above is not visually recognized from the stacking direction (i.e., a thickness direction) because the end of the metal layer 17 on the side on which the first electrode 14 is disposed overlaps with the first electrode 14, with the first insulating layer 16 in between. Furthermore, because the thickness of the first insulating layer 16 is about several micrometers at most, the light emitted from the active layer 12 barely leaks to the outside directly through the gap as mentioned above.

Examples of materials of the metal layer 17 include materials that shield or reflect the light emitted from the active layer 12, e.g., Ti, Al, copper (Cu), Au, Ni, or their alloys. A thickness of the metal layer 17 is, for example, about 0.1 μm to 1 μm both inclusive, and is a substantially uniform thickness. It is to be noted that the metal layer 17 may have the non-uniformity in the thickness caused by the manufacture errors.

The second insulating layer 18 prevents short circuits between a conductive material (e.g., a solder, a plating, and/or a sputtered metal) and the metal layer 17. The conductive material joins the pad electrode 19 and the mounting substrate together, in mounting the light emitting element 10 on the mounting substrate (undepicted). The second insulating layer 18 is provided in contact with a surface of the metal layer 17 and with the surface of the first insulating layer 16 (the exposed surface 16A as mentioned above). The second insulating layer 18 is provided on an entirety of the surface of the metal layer 17, and is provided on an entirety or a part of the exposed surface 16A of the first insulating layer 16. In other words, the second insulating layer 18 is provided from the exposed surface 16A of the first insulating layer 16 to the surface of the metal layer 17. The metal layer 17 is covered with the first insulating layer 16 and the second insulating layer 18. Examples of materials of the second insulating layer 18 include SiO₂, SiN, Al₂O₃, TiO₂, and TiN. Moreover, the second insulating layer 18 may be made of a plurality of materials out of the materials as exemplified above. A thickness of the second insulating layer 18 is, for example, about 0.1 μm to 1 μm, and is a substantially uniform thickness. It is to be noted that the second insulating layer 18 may have the non-uniformity in the thickness caused by the manufacture errors.

The pad electrode 19 is an electrode lead out from the first electrode 14. The pad electrode 19 is provided from the exposed surface 14A of the first electrode 14 to the surface of the first insulating layer 16 and a surface of the second insulating layer 18. The pad electrode 19 is electrically coupled to the first electrode 14. A part of the pad electrode 19 is superposed on a part of the metal layer 17, with the second insulating layer 18 in between. In other words, the pad electrode 19 is insulated and separated (electrically separated) from the metal layer 17 by the second insulating layer 18. The pad electrode 19 is made of a material that reflects, at high reflectivity, the light emitted from the active layer 12, e.g., Ti, Al, Cu, Au, Ni, or their alloys. Moreover, the pad electrode 19 may be made of a plurality of materials out of the materials as exemplified above.

The pad electrode 20 is an electrode lead out from the second electrode 15. The pad electrode 20 is provided from the exposed surface 15A of the second electrode 15 to the surface of the first insulating layer 16 and the surface of the second insulating layer 18. The pad electrode 20 is electrically coupled to the second electrode 15. A part of the pad electrode 20 is superposed on a part of the metal layer 17, with the second insulating layer 18 in between. In other words, the pad electrode 20 is insulated and separated (electrically separated) from the metal layer 17 by the second insulating layer 18. As materials of the pad electrode 20, similar materials to those of the pad electrode 19 may be utilized. The pad electrode 20 may be made of, for example, Ti, Al, Cu, Au, Ni, or their alloys, or alternatively, the pad electrode 20 may be made of a plurality of materials out of the materials as exemplified above.

There is a gap between an end of the pad electrode 19 (and the pad electrode 20) and the metal layer 17. The gap is as large as the thickness of the second insulating layer 18. However, the gap as mentioned above is not visually recognized in the stacking direction (i.e., the thickness direction), because the end of the pad electrode 19 (and the pad electrode 20) is superposed on the end of the metal layer 17 on the side on which the first electrode 14 is disposed. Furthermore, the thickness of the second insulating layer 18 is about several micrometers at most. In addition, the first electrode 14 (and the second electrode 15), the end of the metal layer 17 on the side on which the first electrode 14 is disposed, and the end of the pad electrode 19 (and the pad electrode 20) overlap with one another. Accordingly, a path that goes from the active layer 12 to the outside through the first insulating layer 16 and the second insulating layer 18 meanders in an S shape. That is, the path through which the light emitted from the active layer 12 may pass meanders in the S shape. From the forgoing, the first insulating layer 16 and the second insulating layer 18 that are utilized as insulators for the metal layer 17 may serve as the path that goes from the active layer 12 to the outside. But the path is extremely narrow, and in addition, is shaped as an S. This provides a structure that barely causes the light emitted from the active layer 12 to leak to the outside.

Moreover, between the first electrode 14 and the pad electrode 19, provided is a reflection layer 21. The reflection layer 21 reflects the light emitted in the active layer 12 toward the side on which the first electrode is disposed, toward the side on which the light extraction surface S₂ is disposed. The reflection layer 21 is made of a highly reflective material. Examples of the highly reflective material include metal materials such as Ag and Al.

In this embodiment, as mentioned above, the pad electrode 20 is provided with a larger thickness than the pad electrode 19. The thicknesses of the pad electrode 19 and the pad electrode 20 alleviate inclination (refer to FIG. 33) caused by the shape of the light emitting element 10, in mounting the light emitting element 10 on the mounting substrate. The inclination depends on the shape of the light emitting element 10. Specifically, the thicknesses of the pad electrode 19 and the pad electrode 20 are so adjusted as to alleviate asymmetry of an orientation shape (light intensity distribution) of the light emitted from the active layer 12. The asymmetry is caused by the inclination.

### 7-2. Configuration of Light Emitting Unit

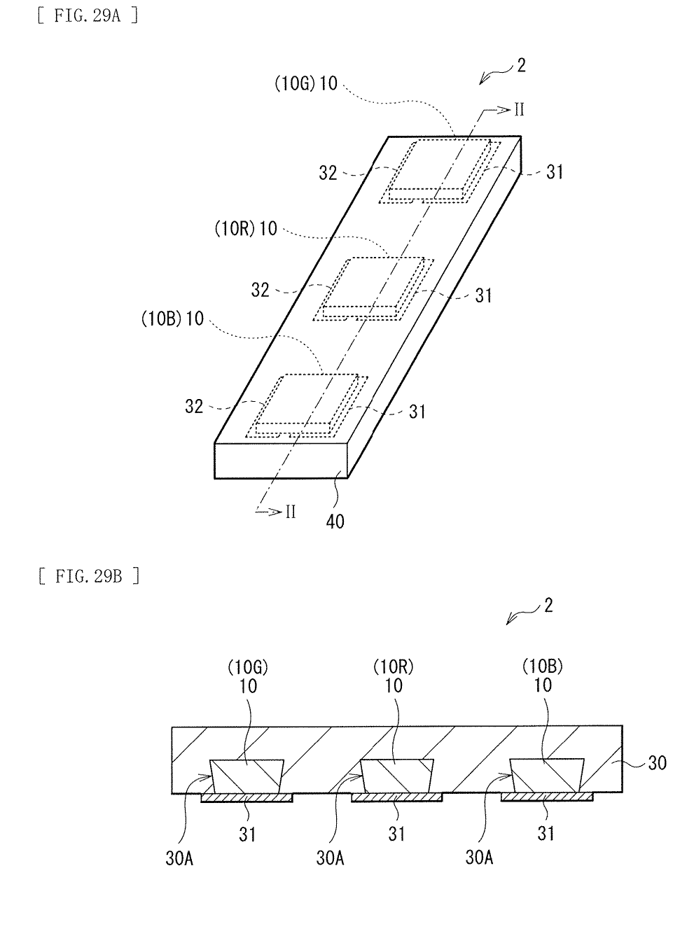

FIG. 29A illustrates, in a perspective, one example of a schematic configuration of a light emitting unit 2. FIG. 29B illustrates one example of a cross-sectional configuration along a line II-II of the light emitting unit 2 illustrated in FIG. 29A. The light emitting unit 2 is applicable as, for example, the pixel P as mentioned above, and is a micro-package in which a plurality of the light emitting elements 10 are covered with a resin having a small thickness.

In the light emitting unit 2, the light emitting element 10 as mentioned above (e.g., the red light emitting element 10R) and the other light emitting elements 10 (e.g., the blue light emitting element 10B or the green light emitting element 10G) are disposed in a line at predetermined intervals. The light emitting unit 2 of this embodiment may have a configuration in which the plurality of the light emitting elements 10 are disposed side by side along the row direction, as illustrated in FIG. 14B, for example. Moreover, for example, as illustrated in FIGS. 14A and 16, the plurality of the light emitting elements 10 are disposed in the 2×2 or 2×3 arrangement. In another alternative, as illustrated in FIG. 15B, the plurality of the light emitting elements 10 are in a staggered disposition. Here, description is given on a simplified example in which the red light emitting element 10R, the blue light emitting element 10B, and the green light emitting element 10G are disposed in a line.

As described, the light emitting unit 2 has an elongated shape that extends in, for example, an arrangement direction of the light emitting elements 10. A clearance between the two light emitting elements 10 adjacent to each other is equal to or larger than, for example, a size of each of the light emitting elements 10. It is to be noted that in some cases, the clearance as mentioned above may be smaller than the size of each of the light emitting elements 10.

The light emitting elements 10 emit light in the different wavelength bands from one another. For example, as illustrated in FIG. 29A, the three light emitting elements 10 are constituted by the green light emitting element 10G, the red light emitting element 10R, and the blue light emitting element 10B. The green light emitting element 10G emits the light of the green band. The red light emitting element 10R emits the light of the red band. The blue light emitting element 10B emits the light of the blue band. For example, in a case where the light emitting unit 2 has the elongated shape that extends in the arrangement direction of the light emitting elements 10, the green light emitting element 10G is disposed in the vicinity of, for example, one of shorter sides of the light emitting unit 2. The blue light emitting element 10B is disposed in the vicinity of, for example, another of the shorter sides of the light emitting unit 2, i.e., a shorter side different from the shorter side to which the green light emitting element 10G is close. The red light emitting element 10R is disposed between, for example, the green light emitting element 10G and the blue light emitting element 10B. It is to be noted that a position of each of the red light emitting element 10R, the green light emitting element 10G, and the blue light emitting element 10B is not limited thereto. In the following, however, there may be cases where positional relation of other constituent elements is described on an assumption that the red light emitting element 10R, the green light emitting element 10G, and the blue light emitting element 10B are disposed at the positions as exemplified above.

The light emitting unit 2 further includes, as illustrated in FIGS. 29A and 29B, an insulator body 30, and terminal electrodes 31 and 32. The insulator body 30 is shaped as a chip, and covers each of the light emitting elements 10. The terminal electrodes 31 and 32 are electrically coupled to each of the light emitting elements 10. The terminal electrodes 31 and 32 are disposed on bottom-surface side of the insulator body 30.

The insulator body 30 surrounds and holds each of the light emitting elements 10, from at least side-surface side of each of the light emitting elements 10. The insulator body 30 is made of, for example, a resin material such as silicone, acryl, and epoxy. The insulator body 30 may partly include different materials such as polyimide. The insulator body 30 is provided in contact with side surfaces of each of the light emitting elements 10 and an upper surface of each of the light emitting elements 10. The insulator body 30 has the elongated shape that extends in the arrangement direction of the light emitting elements 10 (e.g., a rectangular parallelepiped shape). A height of the insulator body 30 is larger than a height of each of the light emitting elements 10. A lateral width of the insulator body 30 (a width in a direction of a shorter side) is larger than a width of each of the light emitting elements 10. A size of the insulator body 30 itself is equal to or smaller than, for example, 1 mm. The insulator body 30 has a flake-like shape. An aspect ratio (a maximum height/a maximum lateral width) of the insulator body 30 is small enough to prevent the light emitting unit 2 from being laterally oriented, in transferring the light emitting unit 2, and is equal to or smaller than, for example, ⅕.

As illustrated in FIGS. 29A and 29B, for example, the insulator body 30 has an aperture 30A at a position corresponding to directly below each of the light emitting elements 10. On a bottom surface of each of the apertures 30A, exposed is at least the pad electrode 19 (not illustrated in FIGS. 29A and 29B). The pad electrode 19 is coupled to the terminal electrode 31 through a predetermined conductive member (e.g., the solder and/or a plated metal). Meanwhile, the pad electrode 20 is coupled to the terminal electrode 32 through a predetermined conductive member (e.g., the solder and/or the plated metal). The terminal electrodes 31 and 32 are so constituted as to mainly include, for example, Cu. Parts of surfaces of the terminal electrodes 31 and 32 may be covered with, for example, a material that is hardly oxidized, e.g., Au.

### 7-3. Workings and Effects

Described next are workings and effects of the light emitting element 10 according to this embodiment.

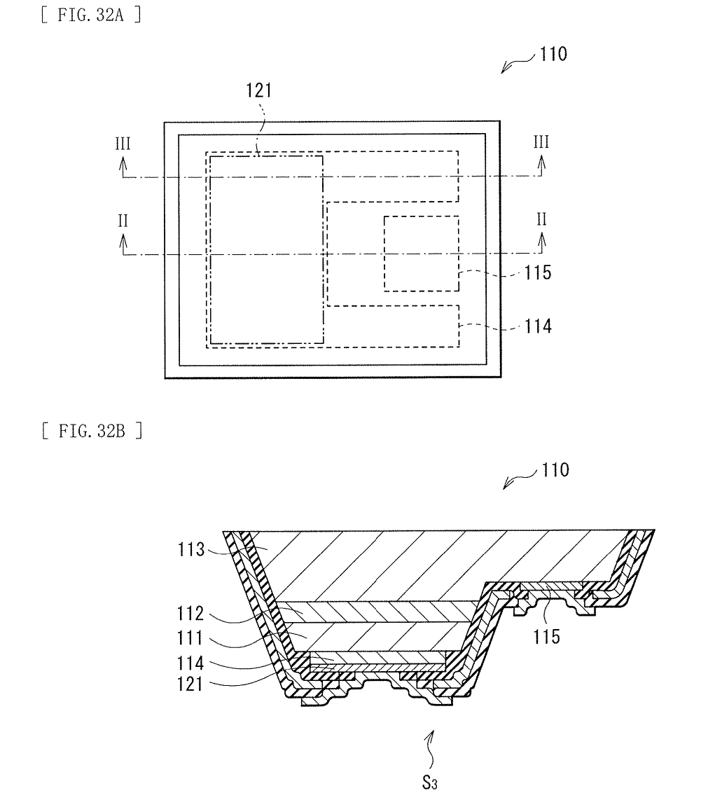

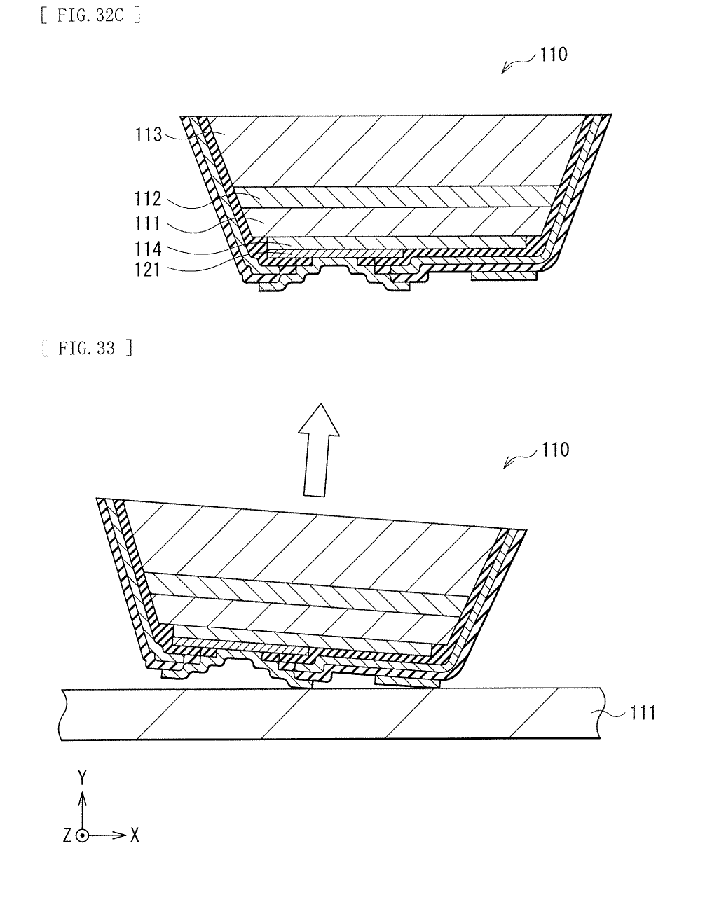

In general, LEDs (light emitting elements) of a Flip-Chip structure make it possible to reduce mounting area. In the Flip-Chip structure, a circuit surface of a large scale integrated circuit (LSI) is directed toward substrate side. The LEDs of the Flip-Chip structure also has an advantage of efficient extraction of light emitted from an active layer, because there is no shielding structures such as electrodes on a light extraction surface. However, a general light emitting element (e.g., a light emitting element 110 as illustrated in FIGS. 32A to 32C) has in-plane displacement of the active layer because of its asymmetrical structure. Accordingly, there occurs deviation in intensity distribution of the light emitted from the active layer.

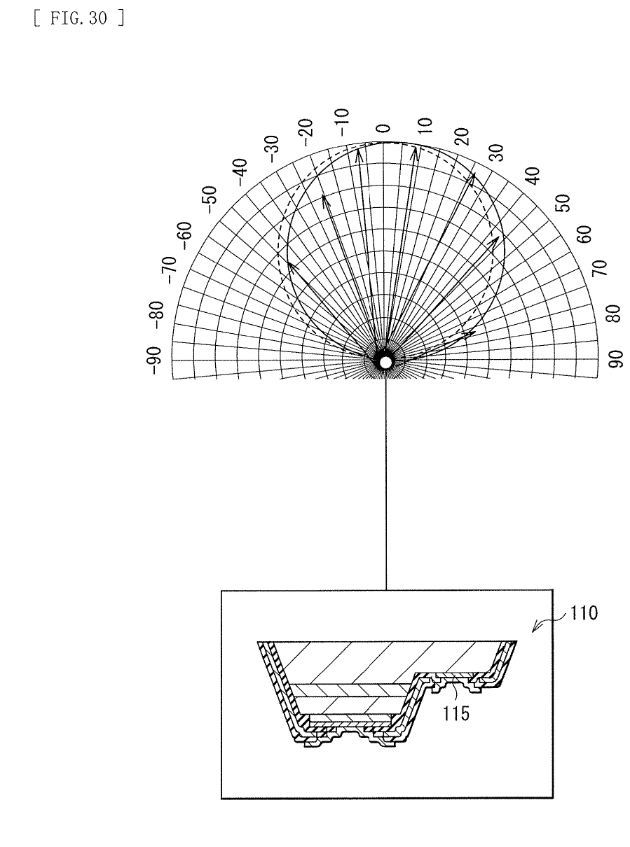

FIG. 30 illustrates light intensity distribution of the general light emitting element 110 with an FFP of a polar coordinate system. As illustrated in a lower part of FIG. 30, in a case where a measurement is made with a second electrode 115 of the light emitting element 110 on right side, a result of the measurement is a circle that is slightly shifted rightward, as compared to completely uniform light intensity distribution denoted by a broken line in a characteristic diagram. Regarding this, for example, in a direction in which “an angle from a point light source” is 50°, light intensity takes higher values, by about 5% to 10% both inclusive, than the case of the completely uniform light intensity distribution. The angle from the point light source is represented, with a directly upward direction of the light emitting element 110 serving as 0°. Moreover, in a direction of −50°, the light intensity takes a lower value, by about 5% to 10% both inclusive, than the case of the completely uniform light intensity distribution.

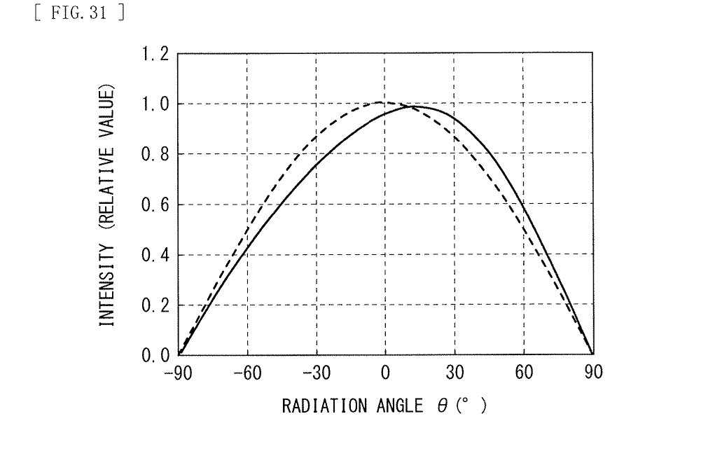

FIG. 31 illustrates the light intensity distribution of the light emitting element 110 with an FFP of an orthogonal coordinate system. As seen in this characteristic diagram as well, it is understood that the light intensity distribution of the light emitting element 110 that takes the higher values is shifted rightward, in the case where the measurement is made with the second electrode 115 of the light emitting element 110 on the right side.

FIGS. 32A to 32C respectively illustrate a plan configuration (FIG. 32A) of the light emitting element 110, and cross-sectional configurations of the light emitting element 110 along a line II-II (FIG. 32B) and a line III-III (FIG. 32C) in FIG. 32A. As seen from FIG. 32B, a part where the second electrode 115 is provided has a recessed shape in the lower surface S₃ because of removal of a first conductive type layer 111 and an active layer 112. The second electrode 115 is electrically coupled to the side of the second conductive type layer 113 on which the lower surface S₃ is disposed. Moreover, as illustrated in FIG. 32C, in a part where the second electrode 115 is not provided, the first electrode 114 side is also thicker, by a thickness of a reflection layer 121 provided in about a half region of the light emitting element 110.

As described, in a case where the light emitting element 110 having irregularity in thickness in the in-plane direction is placed on the mounting substrate, the light emitting element 110 is in an inclined state toward the second electrode 115 as illustrated in FIG. 33, because of its asymmetrical shape. Accordingly, the light intensity distribution has even larger deviation than those illustrated in FIGS. 30 and 31. Therefore, utilizing the light emitting element 110 as light emitting elements of the LED display causes a disadvantage that a non-uniform picture is displayed, with RGB ratios differing between a case where the display is viewed from front and a case where the display is viewed obliquely.

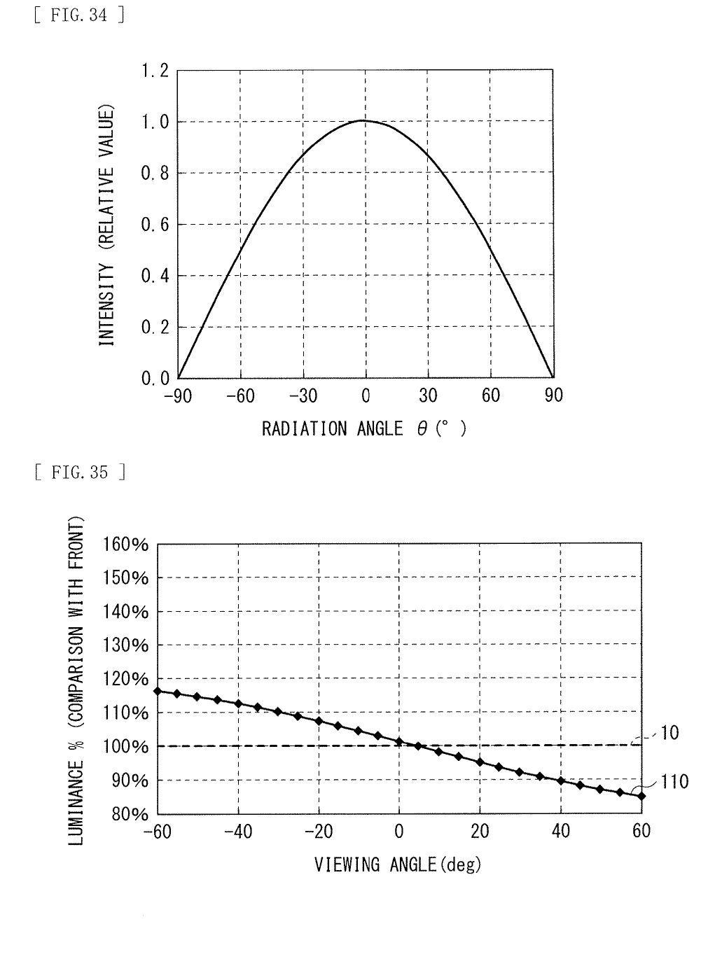

In contrast, in this embodiment, the second electrode 15 has a larger thickness than the first electrode 14. The second electrode 15 is provided on the base of the mesa part M of the light emitting element 10, i.e., the recess in the lower surface S₃. The first electrode 14 is provided on the projection of the lower surface S₃. Specifically, the pad electrode 20 is thicker than the pad electrode 19 of the first electrode 14. The pad electrode 20 is the lead-out electrode that leads out the second electrode 15 from the stacked body that covers the side surface S₁ and the lower surface S₃ of the semiconductor layer. The side surface S₁ and the lower surface S₃ include the outer edge of the second electrode 15. This allows for alleviation of the inclination of the light emitting element 10 at the time of placement on, for example, the mounting substrate, and allows the light extraction surface S₂ of the light emitting element 10 to be substantially parallel to the mounting substrate on which the light emitting element 10 is to be mounted, i.e., a placement surface. Here, the term “substantially parallel” does not necessarily refer to solely a case where the light extraction surface S₂ and the placement surface are completely parallel to each other. The term “substantially parallel” means a state in which the deviation of the light intensity distribution caused by the structure of the light emitting element 10 is canceled. In other words, the term “substantially parallel” means a state in which the light emitting element 10 is devoid of the deviation of the light intensity distribution, and the light extraction surface S₂ of the light emitting element 10 is inclined, for example, about 0° to 20° both inclusive, toward the mesa part M, with respect to the placement surface, so as to provide, for example, the uniform intensity distribution in FIG. 31, or to provide the light intensity distribution as illustrated in FIG. 34. The uniform intensity distribution in FIG. 31 is denoted by the broken line in the characteristic diagram represented by the FFP of the polar coordinate system. The light intensity distribution as illustrated in FIG. 34 is symmetrical in the right-left direction with an angle 0° as an axis of symmetry.

Accordingly, utilizing the light emitting element 10 according to this embodiment as, for example, the display pixel (the pixel P) of the display apparatus 1 as mentioned above makes it possible to provide the LED display having uniform luminance at any viewing angle, unlike the general light emitting element 110 whose luminance changes with the viewing angle as illustrated in FIG. 35.

As described, in the light emitting element 10 in this embodiment, the semiconductor layer includes the stack of the first conductive type layer 11, the active layer 12, and the second conductive type layer 13 in the order. The first electrode 14 (the pad electrode 19) and the second electrode 15 (the pad electrode 20) are provided on the lower surface S₃ of the semiconductor layer, and are respectively electrically coupled to the first conductive type layer 11 and the second conductive type layer 13. The thickness of the second electrode 15 (the pad electrode 20) provided in the recess is larger than the first electrode 14 (the pad electrode 19). Accordingly, the deviation of the light intensity distribution because of the asymmetrical structure of the light emitting element 10 is corrected. Hence, it is possible to reduce the deviation of the viewing angle characteristics.

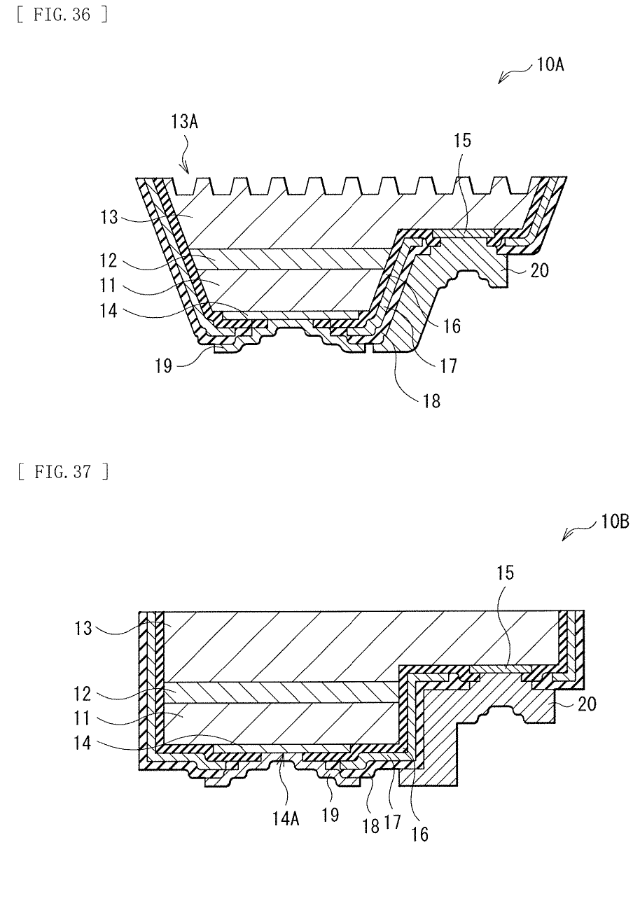

It is to be noted that in the light emitting element 10, the light extraction surface S₂ may be subjected to special processing, to enhance performance of light. For example, as in a light emitting element 10A illustrated in FIG. 36, the light extraction surface S₂ may be provided with concavity and convexity. Forming a plurality of concaved parts 13A in the surface of the second conductive type layer 13 makes it possible to extract the light emitted from the active layer 12 in various directions. This leads to further uniformization of light intensity distribution of the light emitting element 10A.

Moreover, in the light emitting element 10 according to this embodiment, as illustrated in FIG. 28A, the light extraction surface S₂ has the structure in which the second conductive type layer 13 is exposed, with no structural bodies provided thereon. However, for example, a conductive layer and/or an insulating layer that transmits light may be provided.

Furthermore, the side surface of the light emitting element 10, specifically, the side surface S₁ of the semiconductor layer may be a vertical surface that is orthogonal to the stacking direction of the semiconductor layer, as in a blue light emitting element 10B illustrated in FIG. 37. In another alternative, the side surface of the light emitting element 10, or the side surface S₁ of the semiconductor layer may be a reverse-tapered side surface that is widened toward the lower surface S₃, oppositely to the inclination of the side surface S₁ of the light emitting element 10 illustrated in the figures such as FIG. 28A.

In addition, in this embodiment, the stacked body is provided on the side surface S₁ and the lower surface S₃ of the semiconductor layer. However, it is not necessary to provide the stacked body. Solely the first insulating layer 16 may be provided on the side surface S₁ and the lower surface S₃ of the semiconductor layer.

### Fourth Embodiment

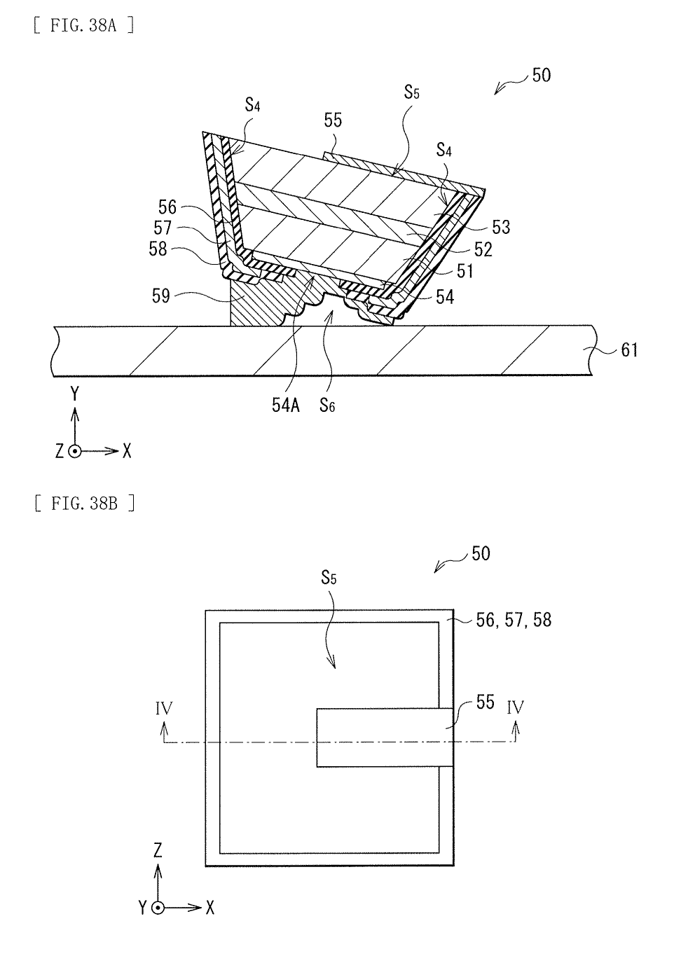

FIG. 38A illustrates a cross-sectional configuration of a light emitting element (a light emitting element 50) according to a fourth embodiment of the disclosure. FIG. 38B illustrates a plan configuration of the light emitting element 50 illustrated in FIG. 38A. It is to be noted that FIG. 38A illustrates a cross-section along a line IV-IV of the light emitting element 50 illustrated in FIG. 38B. The light emitting element 50 is an LED chip having a structure with upper and lower electrodes. The light emitting element 50 is utilized as, for example, the blue light emitting element 10B, the green light emitting element 10G, and the red light emitting element 10R disposed in the display element (the pixel P) of the forgoing display apparatus 1, as with the light emitting element 10 described in the forgoing third embodiment.

In the light emitting element 50, the semiconductor layer includes a first conductive type layer 51, an active layer 52, and a second conductive type layer 53. A first electrode 54 and a second electrode 55 are respectively electrically coupled to a lower surface (a lower surface S₆) and an upper surface (a light extraction surface S₅) of the semiconductor layer. The second electrode 55 is provided in in-plane asymmetry in the light extraction surface S₅. The light emitting element 50 according to this embodiment has a configuration in which the first electrode 54 has a thickness varied in the in-plane direction. The first electrode 54 is provided on the lower surface S₆ of the semiconductor layer. Specifically, in a plane of the light extraction surface S₅, the light emitting element 50 according to this embodiment has a configuration in which the thickness of the first electrode 54 is smaller as a region in which the second electrode 55 is provided is larger, and the thickness of the first electrode 54 is larger as the region in which the second electrode 55 is provided is smaller. It is to be noted that FIGS. 38A and 38B schematically illustrate the configuration of the light emitting element 50, and may be different in dimensions and shapes from reality.

### 8-1. Configuration of Light Emitting Element

The light emitting element 50 is the solid light emitting element that emits the light of the predetermine wavelength body through the upper surface (the light extraction surface S₅). To be specific, the light emitting element 50 is the LED chip. The LED chip refers to those in the cut-out state from the wafer utilized in the crystal growth, instead of those of the package type that are covered with, for example, the molded resin. The LED chip has the size of, for example, 5 μm to 100 mm both inclusive, and is what is called the micro LED. The plan shape of the LED chip is, for example, the substantially square shape. The LED chip has the flake-like shape. The aspect ratio (height/width) of the LED chip is, for example, equal to or larger than 0.1 and smaller than 1.

As described, the light emitting element 50 includes the semiconductor layer. The semiconductor layer includes the stack of the first conductive type layer 51, the active layer 52, and the second conductive type layer 53 in the order, with the second conductive type layer 53 serving as the light extraction surface S₅ (the second surface). In the semiconductor layer, a side surface S₄ constitutes an inclined surface that crosses with the stacking direction, as illustrated in FIG. 38A, for example. Specifically, the side surface S₄ constitutes the inclined surface that causes the light emitting element 50 to have an inverted trapezoid cross-section. Thus, making the side surface S₄ tapered makes it possible to enhance the light extraction efficiency through the light extraction surface S₅.

Moreover, as illustrated in FIG. 38A, the light emitting element 50 according to this embodiment includes a stacked body including a first insulating layer 56, a metal layer 57, and a second insulating layer 58. The stacked body is a layer provided from the side surface S₄ of the semiconductor layer to a surface confronted with the light extraction surface S₅ (the lower surface S₆). The stacked body provided on the lower surface S₆ (specifically, the first insulating layer 56) is provided over an outer edge of a surface of the first electrode 54. In other words, the first electrode 54 includes an exposed surface 54A that is free from coverage with the stacked body. On the exposed surface 54A, provided is a pad electrode 59 as a lead-out electrode. In this embodiment, the pad electrode 59 is so processed as to allow the thickness of the pad electrode 59 of the first electrode 54 to gradually increase toward a direction opposite to a direction of extension of the second electrode 55 provided on the light extraction surface S₅. Thus, adjustment is so made as to allow the light extraction surface S₅ of the light emitting element 50 to incline toward side on which the region in which the second electrode 55 is provided is larger.

In the following, description is given of each member that constitutes the light emitting element 50.

As to the first conductive type layer 51, the active layer 52, and the second conductive type layer 53 that constitute the semiconductor layer, materials are selected as appropriate in accordance with the light of the desired wavelength bands. Specifically, in the case where the light of the green band or the light of the blue band is to be obtained, it is preferable that for example, the InGaN-based semiconductor materials be utilized. In the case where the light of the red band is to be obtained, it is preferable that for example, the AlGaInP-based semiconductor materials be utilized.

The first electrode 54 is in contact with the first conductive type layer 51, and is electrically coupled to the first conductive type layer 51. In other words, the first electrode 54 is in ohmic-contact with the first conductive type layer 51. The first electrode 54 is the metal electrode, and is constituted as the multi-layered body of, for example, titanium (Ti)/platinum (Pt)/gold (Au) or an alloy of gold and germanium (Au—Ge)/nickel (Ni)/Au. In addition, the first electrode 54 may be so constituted as to include the metal material having the high reflectivity such as silver (Ag) and aluminum (Al).

The second electrode 55 is in contact with the second conductive type layer 53, and is electrically coupled to the second conductive type layer 53. In other words, the second electrode 55 is in ohmic-contact with the second conductive type layer 53. The second electrode 55 is provided in the in-plane asymmetry, on the light extraction surface S₅ of the second conductive type layer 53. Specifically, for example, the second electrode 55 extends in an X-axis direction from near a center of the light extraction surface S₅, and shields a part of the light extraction surface. The second electrode 55 is the metal electrode, and is constituted as the multi-layered body of, for example, Ti/Pt/Au or Au—Ge/Ni/Au, as with the first electrode. The second electrode 55 may be so constituted as to further include the metal material having the high reflectivity such as Ag and Al. The first electrode 54 and the second electrode 55 may each be constituted by the single electrode, or alternatively, the first electrode 54 and the second electrode 55 may each be constituted by the plurality of electrodes.

The stacked body is a layer provided from the side surface S₄ of the semiconductor layer to the lower surface S₆. The stacked body has a configuration in which the first insulating layer 56, the metal layer 57, and the second insulating layer 58 are stacked in the order on the semiconductor layer. The stacked body covers at least an entirety of the side surface S₄, and is provided from a confronted region with the side surface S₄ to a part of a confronted region with the first electrode 54. It is to be noted that the first insulating layer 56, the metal layer 57, and the second insulating layer 58 are each a thin layer, and are each formed by the thin film forming process such as the CVD, the evaporation, and the sputtering. That is, out of the stacked body, at least the first insulating layer 56, the metal layer 57, and the second insulating layer 58 are not formed by the thick film forming process such as the spin coating, by the resin molding, or by the potting.

The first insulating layer 56 forms the electrical insulation between the metal layer 57 and the semiconductor layer. The first insulating layer 56 is provided from an end of the side surface S₄ on side on which the base of the mesa part M is disposed, to the outer edge of the surface of the first electrode 54. In other words, the first insulating layer 56 is provided in contact with an entirety of the side surface S₄, and is further provided in contact with the outer edge of the surface of the first electrode 54. Examples of materials of the first insulating layer 56 include the transparent material with respect to light emitted from the active layer 52, e.g., SiO₂, SiN, Al₂O₃, TiO₂, and TiN. A thickness of the first insulating layer 56 is, for example, about 0.1 μm to 1 μm both inclusive, and is a substantially uniform thickness. It is to be noted that the first insulating layer 56 may have the non-uniformity in the thickness caused by the manufacture errors.

The metal layer 57 shields or reflects the light emitted from the active layer 52. The metal layer 57 is provided in contact with a surface of the first insulating layer 56. The metal layer 57 is provided, in the surface of the first insulating layer 56, from an end on side on which the light extraction surface S₅ is disposed, to a position slightly retreating from an end on side on which the first electrode 54 is disposed. In other words, the first insulating layer 56 includes an exposed surface 56A in a confronted part with the first electrode 54. The exposed surface 56A is free from coverage with the metal layer 57.

An end of the metal layer 57 on the side on which the light extraction surface S₅ is disposed is provided on a same surface as the end of the first insulating layer 56 on the side on which the light extraction surface S₅ is disposed (a same surface as the light extraction surface S₅). Meanwhile, an end of the metal layer 57 on the side on which the first electrode 54 is disposed is provided in a confronted region with the first electrode 54, and is superposed on a part of the metal layer 57, with the first insulating layer 56 in between. That is, the metal layer 57 is insulated and separated (electrically separated) by the first insulating layer 56 from the semiconductor layer and the first electrode 54.

There is a gap between the end of the metal layer 57 on the side on which the first electrode 54 is disposed and the metal layer 57. The gap is as large as the thickness of the first insulating layer 56. However, the gap as mentioned above is not visually recognized from the stacking direction (i.e., the thickness direction) because the end of the metal layer 57 on the side on which the first electrode 54 is disposed overlaps with the first electrode 54, with the first insulating layer 56 in between. Furthermore, because the thickness of the first insulating layer 56 is about several micrometers at most, the light emitted from the active layer 52 barely leaks to the outside directly through the gap as mentioned above.

Examples of materials of the metal layer 57 include materials that shield or reflect the light emitted from the active layer 52, e.g., Ti, Al, copper (Cu), Au, Ni, or their alloys. A thickness of the metal layer 57 is, for example, about 0.1 μm to 1 μm both inclusive, and is a substantially uniform thickness.

It is to be noted that the metal layer 57 may have the non-uniformity in the thickness caused by the manufacture errors.

The second insulating layer 58 prevents the short circuits between the conductive material (e.g., the solder, the plating, and/or the sputtered metal) and the metal layer 57. The conductive material joins the pad electrode 19 and the mounting substrate together, in mounting the light emitting element 50 on the mounting substrate (undepicted). The second insulating layer 58 is provided in contact with a surface of the metal layer 57 and with the surface of the first insulating layer 56 (the exposed surface 54A as mentioned above). The second insulating layer 58 is provided on an entirety of the surface of the metal layer 57, and is provided on an entirety or a part of the exposed surface 16A of the first insulating layer 56. In other words, the second insulating layer 58 is provided from the exposed surface 16A of the first insulating layer 56 to the surface of the metal layer 57. The metal layer 57 is covered with the first insulating layer 56 and the second insulating layer 58. Examples of materials of the second insulating layer 58 include SiO₂, SiN, Al₂O₃, TiO₂, and TiN. Moreover, the second insulating layer 58 may be made of a plurality of materials out of the materials as exemplified above. A thickness of the second insulating layer 58 is, for example, about 0.1 μm to 1 μm, and is a substantially uniform thickness. It is to be noted that the second insulating layer 58 may have the non-uniformity in the thickness caused by the manufacture errors.

The pad electrode 59 is an electrode lead out from the first electrode 54. The pad electrode 59 is provided from the exposed surface 54A of the first electrode 54 to the surface of the first insulating layer 56 and a surface of the second insulating layer 58. The pad electrode 59 is electrically coupled to the first electrode 54. A part of the pad electrode 59 is superposed on a part of the metal layer 57, with the second insulating layer 58 in between. In other words, the pad electrode 59 is insulated and separated (electrically separated) from the metal layer 57 by the second insulating layer 58. The pad electrode 59 is made of the material that reflects, at the high reflectivity, the light emitted from the active layer 52, e.g., Ti, Al, Cu, Au, Ni, or their alloys. Moreover, the pad electrode 59 may be made of a plurality of materials out of the materials as exemplified above.

There is a gap between an end of the pad electrode 59 and the metal layer 57. The gap is as large as the thickness of the second insulating layer 58. However, the gap as mentioned above is not visually recognized in the stacking direction (i.e., the thickness direction), because the end of the pad electrode 59 is superposed on the end of the metal layer 57 on the side on which the first electrode 54 is disposed. Furthermore, the thickness of the second insulating layer 58 is about several micrometers at most. In addition, the first electrode 54, the end of the metal layer 57 on the side on which the first electrode 14 is disposed, and the end of the pad electrode 59 overlap with one another. Accordingly, a path that goes from the active layer 52 to the outside through the first insulating layer 56 and the second insulating layer 58 meanders in an S shape. That is, the path through which the light emitted from the active layer 52 may pass meanders in the S shape. From the forgoing, the first insulating layer 56 and the second insulating layer 58 that are utilized as insulators for the metal layer 57 may serve as the path that goes from the active layer 52 to the outside. But the path is extremely narrow, and in addition, is shaped as an S. This provides a structure that barely causes the light emitted from the active layer 52 to leak to the outside.

In this embodiment, as described above, the pad electrode 59 is so provided as to allow the thickness of the electrode to increase in an opposite direction to the direction of the extension of the second electrode 55. Specifically, as illustrated in FIGS. 38A and 38B, the pad electrode 59 is so processed as to allow the thickness to increase leftward, i.e., oppositely to the direction of the extension, with respect to the second electrode 55 that extends rightward (the X axis direction) from near the center of the light extraction surface S₅. Thus, provided is the light emitting element 50 that is inclined in a direction in which the region in which the second electrode 55 is provided is larger, i.e., a direction in which area shielded by the second electrode 55 is larger.

It is to be noted that there is no limitation as long as the thickness of the pad electrode 59 is larger than the thickness of the pad electrode 59 in the direction of the extension of the second electrode 55. In other words, the thickness of the pad electrode 59 may continuously and gradually increase to opposite side to the direction of the extension of the second electrode 55. Or alternatively, the thickness of the pad electrode 59 may change stepwise. Moreover, the pad electrode 59 may simply have a constant thickness that is larger than the thickness of the pad electrode 59 in the direction of the extension of the second electrode 55.

### 8-2. Configuration of Light Emitting Unit

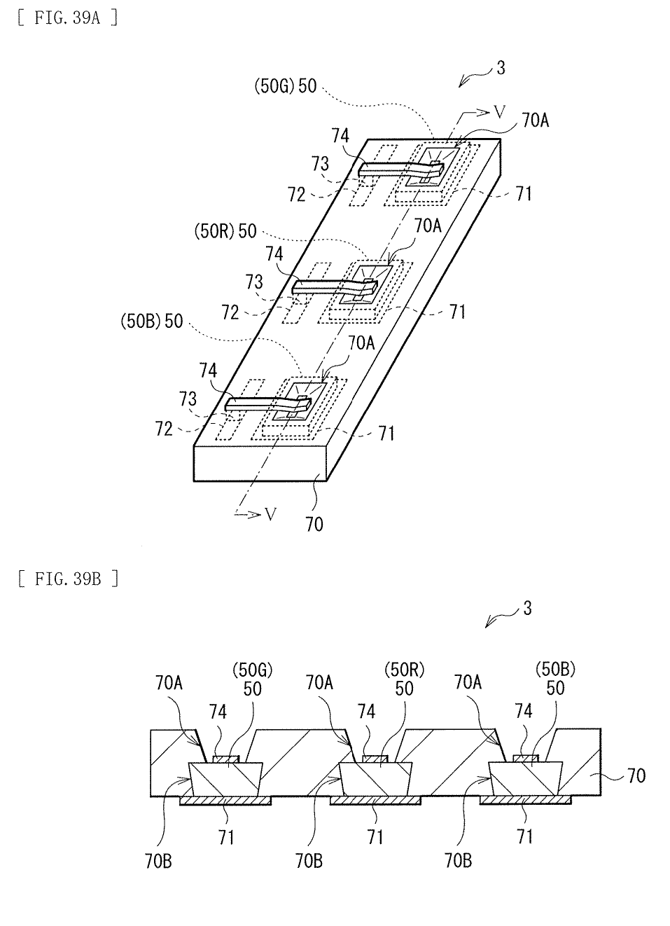

FIG. 39A illustrates, in a perspective, one example of a schematic configuration of a light emitting unit 3. FIG. 39B illustrates one example of a cross-sectional configuration along a line V-V of the light emitting unit 3 illustrated in FIG. 39A. The light emitting unit 3 is applicable as, for example, the pixel P as mentioned above, and is a micro-package in which a plurality of the light emitting elements are covered with a resin having a small thickness. Here, description is given on a simplified example in which the red light emitting element 50R, the blue light emitting element 50B, and the green light emitting element 50G are disposed in a line, as with the forgoing third embodiment.

In the light emitting unit 3, the light emitting element 50 as mentioned above and the other light emitting elements 50 are disposed in a line at predetermined intervals. The light emitting unit 3 has an elongated shape that extends in, for example, an arrangement direction of the light emitting elements 50. A clearance between the two light emitting elements 50 adjacent to each other is equal to or larger than, for example, a size of each of the light emitting elements 50. It is to be noted that in some cases, the clearance as mentioned above may be smaller than the size of each of the light emitting elements 50.

The light emitting elements 50 emit light in the different wavelength bands from one another. For example, as illustrated in FIG. 39A, the three light emitting elements 50 are constituted by the green light emitting element 50G, the red light emitting element 50R, and the blue light emitting element 50B. The green light emitting element 50G emits the light of the green band. The red light emitting element 50R emits the light of the red band. The blue light emitting element 50B emits the light of the blue band. For example, in a case where the light emitting unit 2 has the elongated shape that extends in the arrangement direction of the light emitting elements 50, the green light emitting element 50G is disposed in the vicinity of, for example, one of shorter sides of the light emitting unit 2. The blue light emitting element 50B is disposed in the vicinity of, for example, another of the shorter sides of the light emitting unit 3, i.e., a shorter side different from the shorter side to which the green light emitting element 50G is close. The red light emitting element 50R is disposed between, for example, the green light emitting element 50G and the blue light emitting element 50B. It is to be noted that a position of each of the red light emitting element 50R, the green light emitting element 50G, and the blue light emitting element 50B is not limited thereto. In the following, however, there may be cases where positional relation of other constituent elements is described on an assumption that the red light emitting element 50R, the green light emitting element 50G, and the blue light emitting element 50B are disposed at the positions as exemplified above.

The light emitting unit 3 further includes, as illustrated in FIGS. 39A and 39B, an insulator body 70 and a terminal electrode 71. The insulator body 70 is shaped as a chip, and covers each of the light emitting elements 50. The terminal electrode 71 is electrically coupled to each of the light emitting elements 50. The terminal electrode 71 is disposed on bottom-surface side of the insulator body 70.

The insulator body 70 surrounds and holds each of the light emitting elements 50, from at least side-surface side of each of the light emitting elements 50. The insulator body 70 is made of, for example, the resin material such as silicone, acryl, and epoxy. The insulator body 70 may partly include the different materials such as polyimide. The insulator body 70 is provided in contact with side surfaces of each of the light emitting elements 50 and an upper surface of each of the light emitting elements 50. The insulator body 70 has the elongated shape that extends in the arrangement direction of the light emitting elements 50 (e.g., the rectangular parallelepiped shape). A height of the insulator body 70 is larger than a height of each of the light emitting elements 50. A lateral width of the insulator body 70 (a width in a direction of a shorter side) is larger than a width of each of the light emitting elements 50. A size of the insulator body 70 itself is equal to or smaller than, for example, 1 mm. The insulator body 70 has a flake-like shape. An aspect ratio (a maximum height/a maximum lateral width) of the insulator body 70 is small enough to prevent the light emitting unit 2 from being laterally oriented, in transferring the light emitting unit 2, and is equal to or smaller than, for example, ⅕.

As illustrated in FIGS. 39A and 39B, for example, the insulator body 70 has an aperture 70A and an aperture 70B at positions respectively corresponding to directly below and directly above each of the light emitting elements 50. On a bottom surface of each of the apertures 70B, exposed is at least the pad electrode 59 (not illustrated in FIGS. 39A and 39B). The pad electrode 59 is coupled to the terminal electrode 71 through the predetermined conductive member (e.g., the solder and/or the plated metal). The terminal electrode 71 is so constituted as to mainly include, for example, Cu. A part of a surface of the terminal electrode 71 may be covered with, for example, the material that is hardly oxidized, e.g., Au. Meanwhile, the second electrode 55 of the light emitting element 50 is coupled to a terminal electrode 72 through a bump 73 and a connection part 74 as illustrated in FIG. 39A. The bump 73 is a columnar conductive member that is embedded in the insulator body 70. The connection part 74 is a strip-shaped conductive member provided on an upper surface of the insulator body 70.

### 2-3. Workings and Effects

Described next are workings and effects of the light emitting element 50 according to this embodiment.

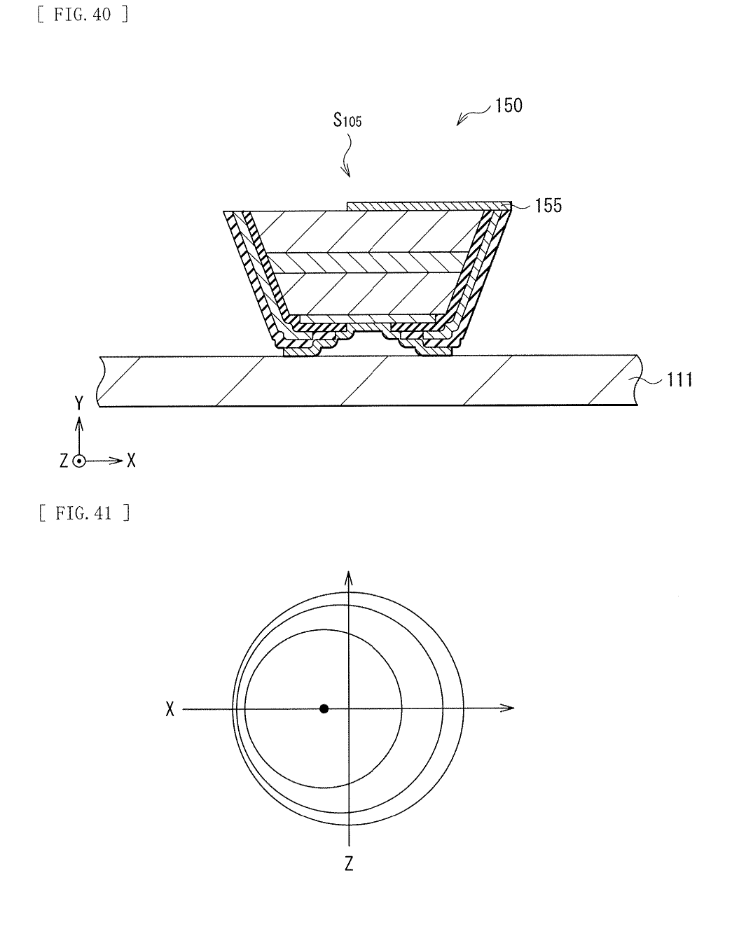

In general, in the LEDs (light emitting elements) having the structure with upper and lower electrodes in which electrodes are lead out from upper and lower sides, the electrodes provided on the upper and lower surfaces each have a substantially uniform thickness, as in a light emitting element 150 illustrated in FIG. 40. Placement is made so as to allow a light extraction surface S₁₀₅ to be substantially parallel to a mounting substrate 1110. However, in a case where an electrode 155 provided on the light extraction surface has an asymmetrical shape in the in-plane direction, for example, as in the light emitting element 50 of this embodiment, the second electrode 55 extends in a certain direction (here, the X axis direction) from near the center of the light extraction surface S₅, the light emitted through the light extraction surface S₅ is shielded by the second electrode 55. That is, as illustrated in FIG. 41, light intensity of the light emitting element 150 exhibits distribution shifted leftward along the X axis from a central part.

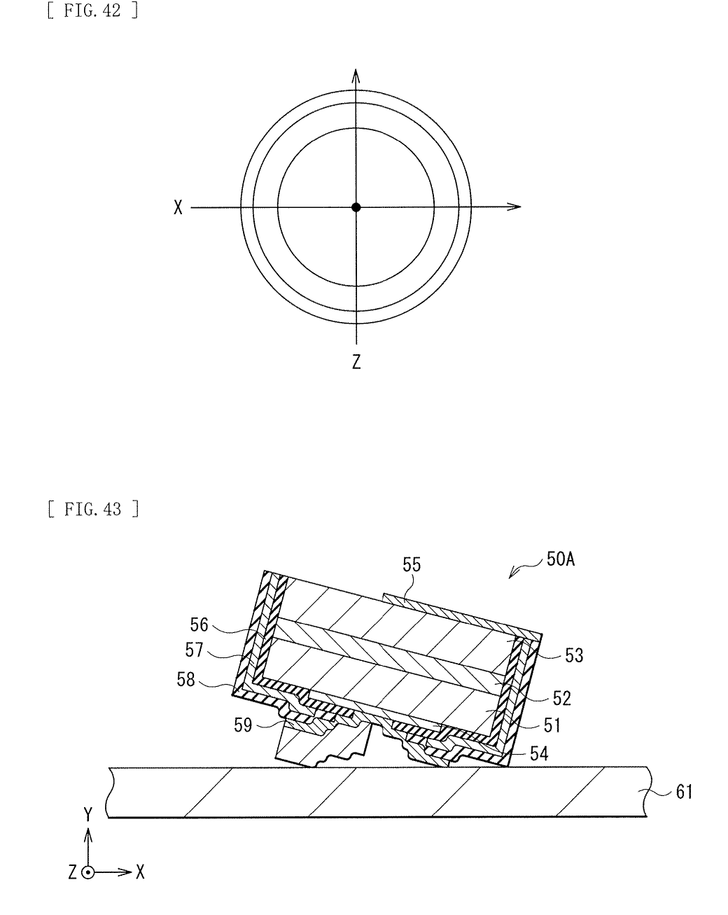

In contrast, in this embodiment, the thickness of the first electrode 54 of the light emitting element 50 is increased toward the opposite side to the direction of the extension of the second electrode 55 provided on the light extraction surface S₅. Specifically, the thickness of the pad electrode 59 is increased in the opposite region to the region in which the second electrode 55 is provided, so as to allow the light extraction surface S₅ to be inclined in the direction in which the area shielded by the second electrode 55 is larger. The pad electrode 59 is electrically coupled to the first electrode 54 and is provided on the lower surface S₆ of the light emitting element 50. Thus, in the light emitting element 50, the light extraction surface S₅ is inclined in the direction in which the region in which the second electrode 55 is provided is larger. In the light intensity distribution, as illustrated in FIG. 42, a center of the light emitting element 50 coincides with a center of the light emission intensity.

Accordingly, utilizing the light emitting element 50 according to this embodiment as, for example, the display pixel (the pixel P) of the display apparatus 1 as mentioned above makes it possible to provide the LED display having uniform luminance at any viewing angle.

As described, in the light emitting element 50 in this embodiment, the semiconductor layer includes the stack of the first conductive type layer 11, the active layer 12, and the second conductive type layer 13 in the order. The first electrode 54 is provided on the lower surface S₆ of the semiconductor layer, whereas the second electrode 55 is provided on the light extraction surface S₅. The thickness of the first electrode 54 is increased toward the opposite side to the direction of the extension of the second electrode 55. Accordingly, the deviation of the light intensity distribution because of the asymmetrical shape of the second electrode 55 in the in-plane direction is corrected. Hence, it is possible to reduce the deviation of the viewing angle characteristics.

It is to be noted that the side surface of the light emitting element 50, specifically, the side surface S₄ of the semiconductor layer may be a vertical surface that is orthogonal to the stacking direction of the semiconductor layer, as in a light emitting element 50A illustrated in FIG. 43. In another alternative, the side surface of the light emitting element 50, or the side surface S₄ of the semiconductor layer may be a reverse-tapered side surface that is widened toward the lower surface S₆, oppositely to the inclination of the side surface S₄ of the light emitting element 10 illustrated in the figures such as FIG. 38A.

In addition, in this embodiment, the stacked body is provided on the side surface S₄ and the lower surface S₆ of the semiconductor layer. However, it is not necessary to provide the stacked body. Solely the first insulating layer 56 may be provided on the side surface S₄ and the lower surface S₆ of the semiconductor layer.

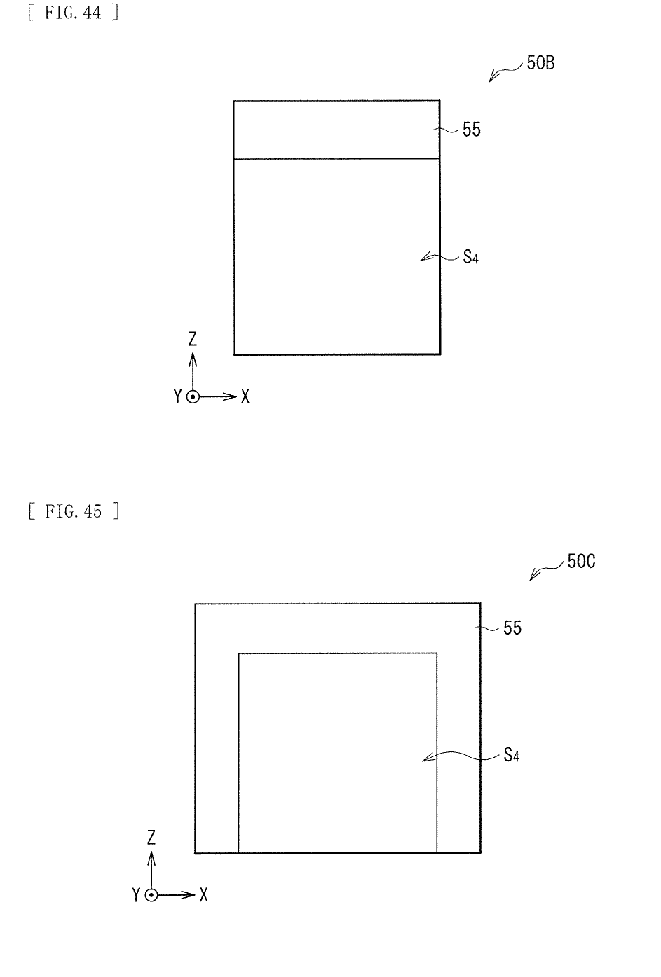

Furthermore, effects of this embodiment is applicable to all the light emitting elements in which the second electrode is provided on the light extraction surface S₅ of the semiconductor layer, and the second electrode has the asymmetrical shape in the in-plane direction. In other words, in this embodiment, the second electrode 55 are so shaped as to extend in the X axis direction from near the center of the light emitting element 50. However, for example, as illustrated in FIG. 44, the embodiment is also applicable to, for example, a blue light emitting element 50B as illustrated in FIG. 44, or to a light emitting element 50C as illustrated in FIG. 45. In the blue light emitting element 50B, for example, the second electrode is provided along a certain side of the light extraction surface S₅ having a substantially rectangular shape. In the light emitting element 50C, the second electrode is provided continuously along three sides of the light extraction surface S₅ having the substantially rectangular shape. Specifically, in the blue light emitting element 50B as illustrated in FIG. 44, the thickness of the first electrode 54 may be increased in a direction of a side confronted with the side along which the second electrode 55 is provided. In the light emitting element 50C as illustrated in FIG. 45, the thickness of the first electrode 54 may be increased in a direction of a region that is devoid of the second electrode 55, i.e., in a direction of a side along which the second electrode 55 is not provided.

### 9. Application Examples

In the following, description is made on application examples of the light emitting elements 10 and 50 described in the forgoing third embodiment and the fourth embodiment. The light emitting elements 10 and 50 of the forgoing third and fourth embodiments are applicable to the display apparatus (e.g., the display apparatus 1) or to the illumination apparatus (e.g., illumination apparatuses 600A, 600B, and 600C). The display apparatus (e.g., the display apparatus 1) includes, as the display pixel (the display pixel P), the light emitting unit 2 or the light emitting unit 3 that respectively utilize the light emitting elements 10 and 50. The illumination apparatus (e.g., the illumination apparatuses 600A, 600B, and 600C) includes the light emitting elements 10 or 50 individually, or in the form of the light emitting unit 2 or the light emitting unit 3. One example is given below.

### Application Example 1

FIG. 46 illustrates, in a perspective, one example of a schematic configuration of the display unit 310 that constitutes, for example, the display apparatus (the tiling device 4) as illustrated in FIG. 13.

The display unit 310 includes the mounting substrate 320 and the element substrate 330 superposed on one another. A surface of the element substrate 330 serves as a picture display surface. The element substrate 330 includes a display region 310A in a central part, and a frame region 310B around the display region 310A. The frame region 310B serves as a non-display region.

FIG. 47 illustrates one example of layout of a region that corresponds to the display region 310A, out of a surface of the mounting substrate 320 on side on which the element substrate 330 is disposed. In the region that corresponds to the display region 310A, out of the surface of the mounting substrate 320, for example, as illustrated in FIG. 47, a plurality of data lines 321 are provided. The plurality of the data lines 321 extend in a predetermined direction, and are disposed side by side at predetermined pitches. In the region that corresponds to the display region 310A, out of the surface of the mounting substrate 320, for example, a plurality of scan lines 322 are further provided. The plurality of the scan lines 322 extend in a direction that crosses with (e.g., are orthogonal to) the data lines 321, and are disposed side by side at predetermined pitches. The data lines 321 and the scan lines 322 are made of, for example, a conductive material such as Cu (copper).

The scan lines 322 are provided on, for example, an uppermost surface, and provided on, for example, an insulating layer (undepicted) provided on a surface of a base. It is to be noted that the base of the mounting substrate 320 may be made of, for example, a glass substrate or a resin substrate. The insulating layer on the base is made of, for example, SiN, SiO₂, or Al₂O₃. Meanwhile, the data lines 321 are provided in a different layer from the uppermost layer that includes the scan lines 322 (e.g., a lower layer than the uppermost layer). For example, the data lines 321 are provided in the insulating layer on the base. On a surface of the insulating layer, for example, a black is provided as necessary, in addition to the scan lines 322. The black is provided for enhancement in contrast, and is made of a material having light absorbing properties. The black is provided in, for example, at least a region that is devoid of pad electrodes 321B and 322B described later, out of the surface of the insulating layer. It is to be noted that the black may be omitted as necessary.

Parts near intersections of the data lines 321 and the scan lines 322 serve as display pixels 323. A plurality of the display pixels 323 are disposed in a matrix in the display region 310A. In each of the display pixels 323, mounted are the light emitting units 2 or the light emitting units 3. The light emitting units 2 each include the plurality of the light emitting elements 10. The light emitting units 3 each include the plurality of the light emitting elements 50. It is to be noted that FIG. 47 exemplifies a case where the single display pixel 323 is constituted by the three light emitting elements, e.g., the red light emitting element 10R, the green light emitting element 10G, and the blue light emitting element 10B, or by the three light emitting elements, e.g., the red light emitting element 50R, the green light emitting element 50G, and the blue light emitting element 50B. Thus, the red light emitting element 10R or the red light emitting element 50R is able to output the light of the red color. The green light emitting element 10G or the green light emitting element 50G is able to output the light of the green color. The blue light emitting element 10B or the blue light emitting element 50B is able to output the light of the blue color.

In the light emitting units 2 and 3, a pair of the terminal electrodes 31 and 32, or a pair of terminal electrodes 61 and 62 are provided for each of the light emitting elements 10 (10R, 10G, and 10B) or for each of the light emitting elements 50 (50R, 50G, and 50B). Moreover, one of the terminal electrodes, e.g., the terminal electrode 31 or the terminal electrode 61 is electrically coupled to the data line 321. Another of the terminal electrodes, e.g., the terminal electrode 32 or the terminal electrode 62 is electrically coupled to the scan line 322. For example, the terminal electrode 31 or the terminal electrode 61 is electrically coupled to the pad electrode 321B. The pad electrode 321B is at a tip of a branch 321A provided on the data line 321. Moreover, for example, the terminal electrode 32 or the terminal electrode 62 is electrically coupled to the pad electrode 322B. The pad electrode 322B is at a tip of a branch 322A provided on the scan line 322.

Each of the pad electrodes 321B and 322B is provided on, for example, the uppermost layer, and is provided at a location at which each of the light emitting units 2 and 3 is mounted, as illustrated in FIG. 47, for example. Here, the pad electrodes 321B and 322B are made of, for example, a conductive material such as Au (gold).

On the mounting substrate 320, for example, a plurality of supports (undepicted) are further provided. The plurality of the supports regulate an interval between the mounting substrate 320 and the element substrate 330. The supports may be provided in a confronted region with the display region 310A, or alternatively, the supports may be provided in a confronted region with the frame region 310B.

The element substrate 330 is made of, for example, a glass substrate or a resin substrate. A surface of the element substrate 330 on side on which the light emitting units 2 or 3 are provided may be flat, but it is preferable that the surface of the element substrate 330 on the side on which the light emitting units 2 or 3 are provided be a rough surface. The rough surface may be provided over an entirety of the confronted region with the display region 310A, or alternatively, the rough surface may be provided solely in confronted regions with the display pixels 323. The rough surface has unevenness that are fine enough to cause diffusion of entering light, in a case where the light emitted from the light emitting element 10 (10R, 10G, and 10B) or the light emitting element 50 (50R, 50G, and 50B) enters the rough surface. The unevenness of the rough surface may be fabricated by, for example, sandblasting or etching.

A driver circuit drives each of the display pixels 323 (each of the light emitting units 2 or 3) on the basis of a picture signal. The driver circuit is constituted by, for example, a data driver and a scan driver. The data driver drives the data lines 321 coupled to the display pixels 323. The scan driver drives the scan lines 322 coupled to the display pixels 323. The driver circuit may be mounted on, for example, the mounting substrate 320, or alternatively, the driver circuit may be provided separately from the display unit 310, and be coupled to the mounting substrate 320 through a wiring (undepicted).

### Application Examples 2

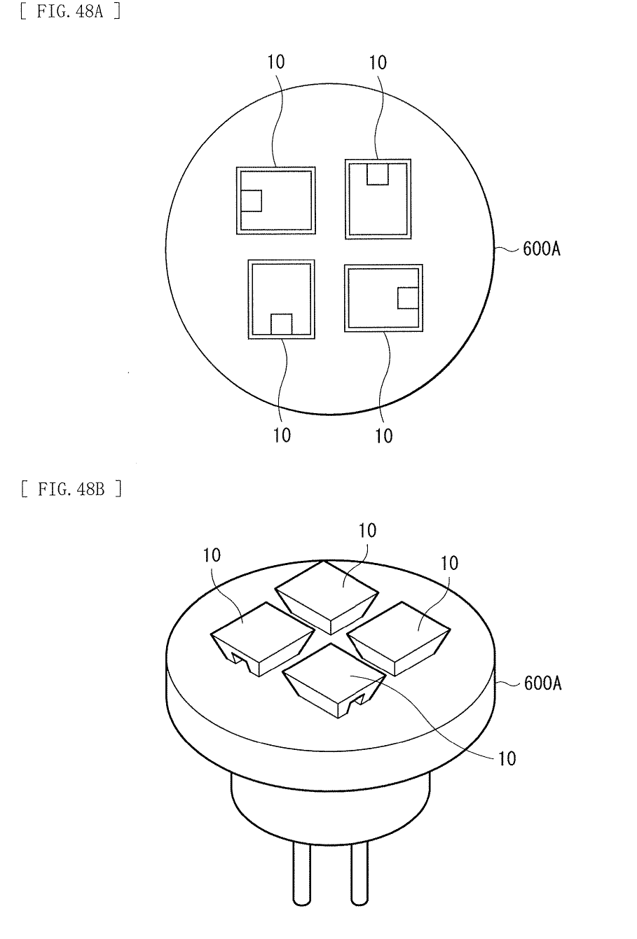

FIGS. 48A and 48B illustrate a plan configuration (FIG. 48A) and a configuration in a perspective direction (FIG. 48B) of the illumination apparatus 600A as one example of the illumination apparatus that utilizes the light emitting elements 10 or the light emitting elements 50. As illustrated in FIGS. 48A and 48B, the light emitting elements 10 or the light emitting elements 50 are arranged on a disk-shaped mounting stage (the mounting substrate). For example, the four light emitting elements 10 are disposed in, for example, point symmetry. It goes without saying that as to methods of disposing the light emitting elements 10, the light emitting elements 10 may be disposed by other methods than the point symmetry.

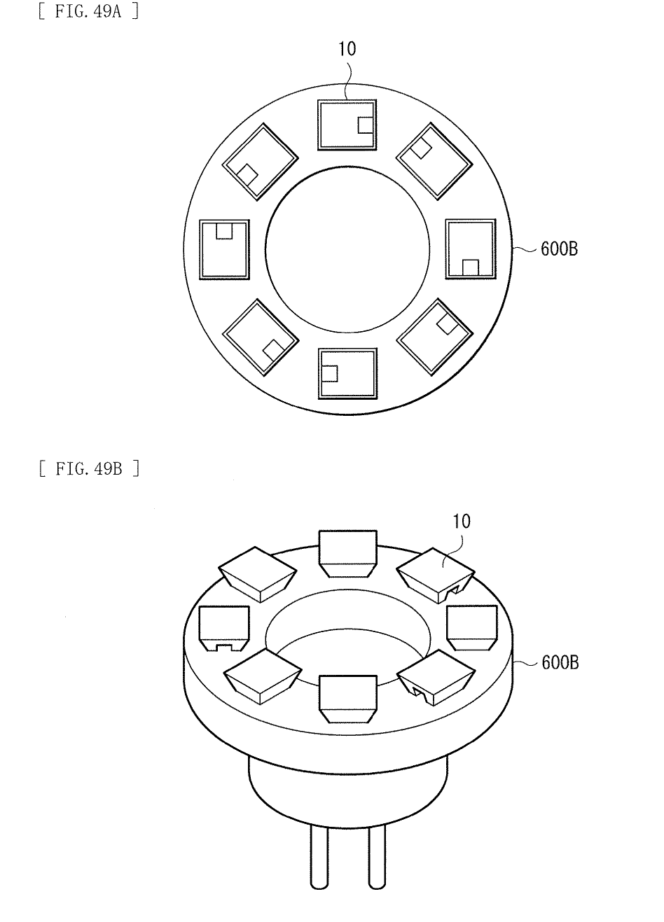

FIGS. 49A and 49B illustrates a plan configuration (FIG. 49A) and a configuration in a perspective direction (FIG. 49B) of the illumination apparatus 600B as another example of the illumination apparatus that utilizes the light emitting elements 10 or the light emitting elements 50. As illustrated in FIGS. 49A and 49B, the light emitting elements 10 or the light emitting elements 50 are disposed on an annular mounting stage (the mounting substrate). For example, the eight light emitting elements 10 are disposed.

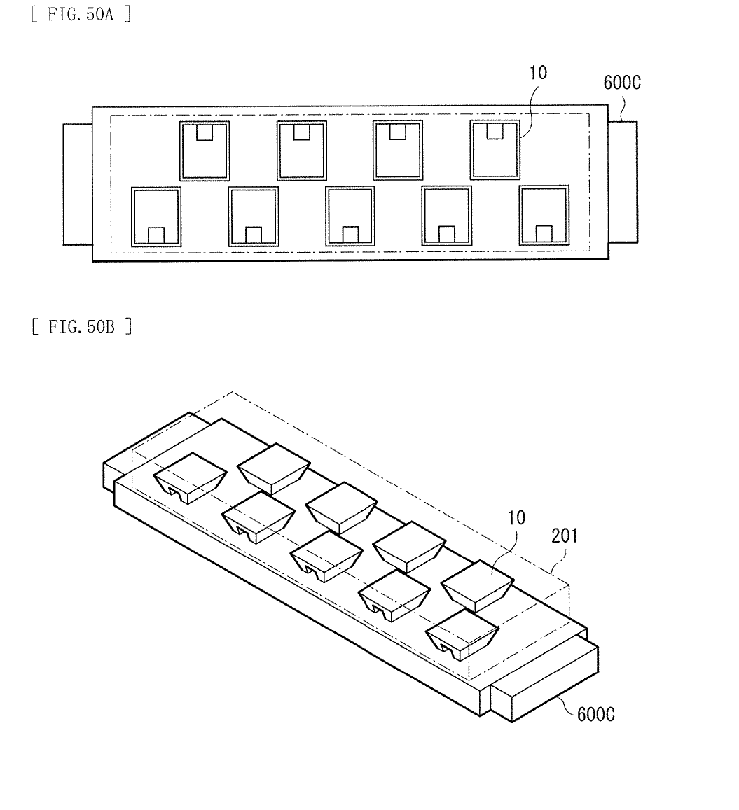

FIGS. 50A and 50B illustrate a plan configuration (FIG. 50A) and a configuration in a perspective direction (FIG. 50B) of the illumination apparatus 600C as another example of the illumination apparatus that utilizes the light emitting elements 10 or the light emitting elements 50. As illustrated in FIGS. 50A and 50B, for example, the nine light emitting elements 10 are disposed on a rectangle-shaped mounting stage. The illumination apparatus 600C may include a cover for a ceiling light.

Although description has been made by giving the first to the fourth embodiments and the modification examples 1-9, the contents of the disclosure are not limited to the above-mentioned example embodiments and may be modified in a variety of ways. For example, in the forgoing example embodiments, description is made by exemplifying the case where the LEDs of the three primary colors of R, G, and B are disposed as the light emitting elements of the disclosure. However, LEDs of other colors may be further disposed. In other words, the disclosure is applicable to an LED display of four or more primary colors. Moreover, LEDs of other colors may be included instead of any one of the LEDs of R, G, and B.

Furthermore, in the forgoing example embodiments, exemplified is the case where the light emitting elements of the three primary colors are disposed in the single pixel or in the single unit. However, alternative configuration may be also possible in which solely light emitting elements of two primary colors or a single primary color are disposed. For example, display apparatuses such as a digital signage, or illumination apparatuses do not necessitate the three primary colors, but provide two-color display or single-color display in some cases. The disclosure is also applicable to such cases.

In addition, in the forgoing example embodiments, exemplified are the LEDs as the light emitting elements of the disclosure. However, the disclosure is widely applicable to displays of a spontaneous light emission type that utilize other light emitting elements, e.g., organic electroluminescence elements, or that utilize quantum dots as an active layer.

Moreover, for example, the contents of the disclosure may have the following configuration.

(1)

A display apparatus, including pixels in a plurality, the pixels being two-dimensionally disposed, and the pixels each including light emitting elements of at least a first primary color,

the pixels each or pixel groups each including, as the light emitting elements of the first primary color, a first light emitting element and a second light emitting element that have peak wavelengths of light emission in different wavelength bands from each other, the pixel groups each including two or more adjacent ones of the pixels.

(2)

The display apparatus according to (1), in which

the first light emitting element and the second light emitting elements are disposed, in each of the pixels, in adjacency in a row direction, a column direction, or an oblique direction.

(3)

The display apparatus according to (2), in which

the pixels each include, as the light emitting elements of the first primary color, three or more light emitting elements that have the peak wavelengths of the light emission in the different wavelength bands from one another.

(4)

The display apparatus according to (1), in which

the first light emitting element and the second light emitting element are disposed, in each of the pixel groups, in two or more pixels in adjacency in a row direction, a column direction, or an oblique direction.

(5)

The display apparatus according to (4), in which

the pixel groups each include three or more light emitting elements that have the peak wavelengths of the light emission in the different wavelength bands from one another.

(6)

The display apparatus according to any one of (1) to (5), in which

the first primary color is a blue color.

(7)

The display apparatus according to (6), in which

the pixels each further include a light emitting element of a red color in a singularity and a light emitting element of a green color in a singularity.

(8)

The display apparatus according to (6), in which

the pixels each further include light emitting elements of a red color and light emitting elements of a green color, and

the pixels each or the pixel groups each include, as the light emitting elements of the red color, two or more light emitting elements that have the peak wavelengths of the light emission in the different wavelength bands from one another, and the pixels each or the pixel groups each include, as the light emitting elements of the green color, two or more light emitting elements that have the peak wavelengths of the light emission in the different wavelength bands from one another.

(9)

The display apparatus according to any one of (1) to (5), in which

the first primary color is a red color or a green color.

(10)

The display apparatus according to any one of (1) to (9), in which

a distance from the first light emitting element to the second light emitting element is set at magnitude within a range in which the distance from the first light emitting element to the second light emitting element becomes equal to or smaller than a resolution distance for an eye, the resolution distance varying with a viewing distance.

(11)

The display apparatus according to any one of (1) to (10), in which

a difference between the peak wavelengths of the light emission of the first light emitting element and second light emitting element is 5 nm to 30 nm both inclusive.

(12)

The display apparatus according to any one of (1) to (11), further including:

a correction processor unit that corrects drive signals of the first light emitting element and the second light emitting element; and

a driver unit that performs a light emission drive of the pixels in the plurality, on the basis of the drive signals corrected,

the correction processor unit correcting the drive signals on the basis of a correction coefficient that is set in advance on the basis of the peak wavelengths of the light emission of the first light emitting element and the second light emitting element.

(13)

The display apparatus according to (12), in which

the correction coefficient is set for each of the pixels or for each of the pixel groups.

(14)

The display apparatus according to any one of (1) to (13), in which

the light emitting element is a light emitting diode (an LED).

(15)

The display apparatus according to any one of (1) to (14), in which the display apparatus is constituted by a plurality of light emitting units that are two-dimensionally disposed and each include the pixels in the plurality.

(16)

An illumination apparatus, including units in a plurality, the units being two-dimensionally disposed, and the units each including light emitting elements of at least a first primary color,

the units each or unit groups each including, as the light emitting elements of the first primary color, a first light emitting element and a second light emitting element that have peak wavelengths of light emission in different wavelength bands from each other, the unit groups each including two or more adjacent ones of the pixels.

(17) A light emitting element, including:

a semiconductor layer having a first surface and a second surface, the semiconductor layer including a stack of a first conductive type layer, an active layer, and a second conductive type layer in order from side on which the first surface is disposed; a first electrode that is electrically coupled to the first conductive type layer and is provided on the first surface; and a second electrode that is electrically coupled to the second conductive type layer and is provided on the first surface, the second electrode being thicker than the first electrode.

(18) The light emitting element according to (17), in which the first surface includes a shoulder, the first electrode is provided on a projection of the first surface, and the second electrode is provided on a recess of the first surface.
(19) The light emitting element according to (17) or (18), in which the light emitting element has deviation of a characteristic of light in the second surface.
(20) The light emitting element according to any one of (17) to (19), further including a stacked structure in which an insulating layer and a metal layer are provided in order, the stacked structure being provided on at least a mounting surface out of a surface of the semiconductor layer.
(21) The light emitting element according to (20), in which the stacked structure covers at least an entirety of a side surface of the semiconductor layer.
(22) A light emitting element, including: a semiconductor layer having a first surface and a second surface, the semiconductor layer including a stack of a first conductive type layer, an active layer, and a second conductive type layer in order from side on which the first surface is disposed; a first electrode that is electrically coupled to the first conductive type layer and is provided on the first surface, the first electrode having a thickness varied in an in-plane direction; and a second electrode that is electrically coupled to the second conductive type layer and is provided in in-plane asymmetry in the second surface.
(23) The light emitting element according to (22), in which the thickness of the first electrode is smaller as a region in which the second electrode is provided is larger, and the thickness of the first electrode is larger as the region in which the second electrode is provided is smaller.
(24) The light emitting element according to (22) or (23), in which the second surface has inclination with respect to a mounting substrate.
(25) A semiconductor device, including a plurality of light emitting elements, the plurality of the light emitting elements each including: a semiconductor layer having a first surface and a second surface, the semiconductor layer including a stack of a first conductive type layer, an active layer, and a second conductive type layer in order from side on which the first surface is disposed; a first electrode that is electrically coupled to the first conductive type layer and is provided on the first surface; and a second electrode that is electrically coupled to the second conductive type layer and is provided on the first surface, the second electrode being thicker than the first electrode.
(26) A semiconductor device, including a plurality of light emitting elements, the plurality of the light emitting elements each including: a semiconductor layer having a first surface and a second surface, the semiconductor layer including a stack of a first conductive type layer, an active layer, and a second conductive type layer in order from side on which the first surface is disposed; a first electrode that is electrically coupled to the first conductive type layer and is provided on the first surface, the first electrode having a thickness varied in an in-plane direction; and a second electrode that is electrically coupled to the second conductive type layer and is provided in in-plane asymmetry in the second surface.

This application claims the benefit of Japanese Priority Patent Application JP2015-058649 filed on Mar. 20, 2015 and Japanese Priority Patent Application JP2015-062394 filed on Mar. 25, 2015, the entire contents of both of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A display apparatus, comprising pixels in a plurality, the pixels being two-dimensionally disposed, and the pixels each including light emitting elements of at least a first primary color,
the pixels each or pixel groups each including, as the light emitting elements of the first primary color, a first light emitting element and a second light emitting element that have peak wavelengths of light emission in different wavelength bands from each other, the pixel groups each including two or more adjacent ones of the pixels.

2. The display apparatus according to claim 1, wherein
the first light emitting element and the second light emitting elements are disposed, in each of the pixels, in adjacency in a row direction, a column direction, or an oblique direction.

3. The display apparatus according to claim 2, wherein
the pixels each include, as the light emitting elements of the first primary color, three or more light emitting elements that have the peak wavelengths of the light emission in the different wavelength bands from one another.

4. The display apparatus according to claim 1, wherein
the first light emitting element and the second light emitting element are disposed, in each of the pixel groups, in two or more pixels in adjacency in a row direction, a column direction, or an oblique direction.

5. The display apparatus according to claim 4, wherein
the pixel groups each include three or more light emitting elements that have the peak wavelengths of the light emission in the different wavelength bands from one another.

6. The display apparatus according to claim 1, wherein
the first primary color is a blue color.

7. The display apparatus according to claim 6, wherein
the pixels each further include a light emitting element of a red color in a singularity and a light emitting element of a green color in a singularity.

8. The display apparatus according to claim 6, wherein
the pixels each further include light emitting elements of a red color and light emitting elements of a green color, and
the pixels each or the pixel groups each include, as the light emitting elements of the red color, two or more light emitting elements that have the peak wavelengths of the light emission in the different wavelength bands from one another, and the pixels each or the pixel groups each include, as the light emitting elements of the green color, two or more light emitting elements that have the peak wavelengths of the light emission in the different wavelength bands from one another.

9. The display apparatus according to claim 1, wherein
the first primary color is a red color or a green color.

10. The display apparatus according to claim 1, wherein
a distance from the first light emitting element to the second light emitting element is set at magnitude within a range in which the distance from the first light emitting element to the second light emitting element becomes equal to or smaller than a resolution distance for an eye, the resolution distance varying with a viewing distance.

11. The display apparatus according to claim 1, wherein
a difference between the peak wavelengths of the light emission of the first light emitting element and second light emitting element is 5 nm to 30 nm both inclusive.

12. The display apparatus according to claim 1, further comprising:
a correction processor unit that corrects drive signals of the first light emitting element and the second light emitting element; and
a driver unit that performs a light emission drive of the pixels in the plurality, on a basis of the drive signals corrected,
the correction processor unit correcting the drive signals on a basis of a correction coefficient that is set in advance on a basis of the peak wavelengths of the light emission of the first light emitting element and the second light emitting element.

13. The display apparatus according to claim 12, wherein
the correction coefficient is set for each of the pixels or for each of the pixel groups.

14. The display apparatus according to claim 1, wherein
the light emitting element is a light emitting diode (an LED).

15. The display apparatus according to claim 1, wherein the display apparatus is constituted by a plurality of light emitting units that are two-dimensionally disposed and each include the pixels in the plurality.

16. An illumination apparatus, comprising units in a plurality, the units being two-dimensionally disposed, and the units each including light emitting elements of at least a first primary color,
the units each or unit groups each including, as the light emitting elements of the first primary color, a first light emitting element and a second light emitting element that have peak wavelengths of light emission in different wavelength bands from each other, the unit groups each including two or more adjacent ones of the pixels.

17. A light emitting element, comprising:
a semiconductor layer having a first surface and a second surface, the semiconductor layer including a stack of a first conductive type layer, an active layer, and a second conductive type layer in order from side on which the first surface is disposed;
a first electrode that is electrically coupled to the first conductive type layer and is provided on the first surface; and
a second electrode that is electrically coupled to the second conductive type layer and is provided on the first surface, the second electrode being thicker than the first electrode.

18. The light emitting element according to claim 17, wherein
the first surface includes a shoulder, the first electrode is provided on a projection of the first surface, and the second electrode is provided on a recess of the first surface.

19. The light emitting element according to claim 17, wherein
the light emitting element has deviation of a characteristic of light in the second surface.

20. The light emitting element according to claim 17, further comprising a stacked structure in which an insulating layer and a metal layer are provided in order, the stacked structure being provided on at least a mounting surface out of a surface of the semiconductor layer.

21. The light emitting element according to claim 20, wherein
the stacked structure covers at least an entirety of a side surface of the semiconductor layer.

22. A light emitting element, comprising:
a semiconductor layer having a first surface and a second surface, the semiconductor layer including a stack of a first conductive type layer, an active layer, and a second conductive type layer in order from side on which the first surface is disposed;
a first electrode that is electrically coupled to the first conductive type layer and is provided on the first surface, the first electrode having a thickness varied in an in-plane direction; and
a second electrode that is electrically coupled to the second conductive type layer and is provided in in-plane asymmetry in the second surface.

23. The light emitting element according to claim 22, wherein
the thickness of the first electrode is smaller as a region in which the second electrode is provided is larger, and the thickness of the first electrode is larger as the region in which the second electrode is provided is smaller.

24. The light emitting element according to claim 22, wherein
the second surface has inclination with respect to a mounting substrate.

25. A semiconductor device, comprising a plurality of light emitting elements, the plurality of the light emitting elements each including:
a semiconductor layer having a first surface and a second surface, the semiconductor layer including a stack of a first conductive type layer, an active layer, and a second conductive type layer in order from side on which the first surface is disposed;
a first electrode that is electrically coupled to the first conductive type layer and is provided on the first surface; and
a second electrode that is electrically coupled to the second conductive type layer and is provided on the first surface, the second electrode being thicker than the first electrode.

26. A semiconductor device, comprising a plurality of light emitting elements, the plurality of the light emitting elements each including:
a semiconductor layer having a first surface and a second surface, the semiconductor layer including a stack of a first conductive type layer, an active layer, and a second conductive type layer in order from side on which the first surface is disposed;
a first electrode that is electrically coupled to the first conductive type layer and is provided on the first surface, the first electrode having a thickness varied in an in-plane direction; and
a second electrode that is electrically coupled to the second conductive type layer and is provided in in-plane asymmetry in the second surface.
